(19) United States
(12) Patent Application Publication
(10) Pub. No.: US 2026/0304945 A1
(43) Pub. Date: Oct. 1, 2026

(54) SEMICONDUCTOR DEVICE

(71) Applicant: Samsung Electronics Co., Ltd., Suwon-si (KR)

(72) Inventors: Youngjin Yang, Suwon-si (KR); Nakyoung Yang, Suwon-si (KR); Jehyoung Koo, Suwon-si (KR); Wooseok Park, Suwon-si (KR)

(21) Appl. No.: 19/301,302

(22) Filed: Aug. 15, 2025

(30) Foreign Application Priority Data
Mar. 31, 2025 (KR) 10-2025-0041629

(51) Int. Cl. H10D 84/85; H10D 84/01

(52) U.S. Cl. CPC H10D 84/851; H10D 84/0167; H10D 84/017; H10D 84/0188

(57) ABSTRACT

A semiconductor device comprises a substrate including a PMOSFET region and an NMOSFET region, a pair of first channel patterns spaced apart in a first direction on the PMOSFET region, first source/drain patterns at respective sides of the pair of first channel patterns in a second direction crossing the first direction, a first gate pattern surrounding at least a portion of the first channel patterns, a pair of second channel patterns spaced apart in the first direction on the NMOSFET region, second source/drain patterns at respective sides of the pair of second channel patterns in the second direction, a second gate pattern surrounding at least a portion of the second channel patterns, a first upper insulating structure between a pair of the first source/drain patterns, and a second upper insulating structure between a pair of the second source/drain patterns.

### CROSS-REFERENCE TO RELATED APPLICATION

This application claims priority to and the benefit of Korean Patent Application No. 10-2025-0041629 filed with the Korean Patent Office on Mar. 31, 2025, the entire contents of which are incorporated herein by reference.

### BACKGROUND

A semiconductor is a material that belongs to the intermediate region between conductors and insulators, and is a material that conducts electricity under certain conditions. These semiconductor materials may be used to manufacture various semiconductor devices, such as memory devices. These semiconductor devices may be used in a variety of electronic devices.

As the electronics industry develops, the demands on the characteristics of semiconductor devices are increasing. For example, there is an increasing demand for high reliability, high speed, and/or multi-functionality in semiconductor devices. To meet these demanding characteristics, structures within semiconductor devices are becoming increasingly complex and integrated.

### SUMMARY

In general, the present disclosure is directed toward a semiconductor device with improved reliability.

According to some implementations, the present disclosure is directed to a semiconductor device comprising a substrate including a PMOSFET region and an NMOSFET region, a pair of first channel patterns spaced apart in a first direction on the PMOSFET region, first source/drain patterns disposed at respective both sides of each of the first channel patterns in a second direction crossing the first direction, a first gate pattern surrounding at least a portion of the first channel patterns, a pair of second channel patterns spaced apart in the first direction on the NMOSFET region, second source/drain patterns disposed at respective both sides of each of the second channel patterns in the second direction, a second gate pattern surrounding at least a portion of the second channel patterns, a first upper insulating structure disposed between a pair of the first source/drain patterns disposed at one side of the pair of first channel patterns, and a second upper insulating structure disposed between a pair of the second source/drain patterns disposed at one side of the pair of second channel patterns, wherein the first upper insulating structure is spaced apart from the first source/drain patterns in the first direction, at least a portion of the second upper insulating structure is in contact with the second source/drain patterns, a bottom level of the first upper insulating structure is higher than bottom levels of the pair of first source/drain patterns, and a bottom level of the second upper insulating structure is higher than bottom levels of the pair of second source/drain patterns.

According to some implementations, the present disclosure is directed to a semiconductor device comprising a substrate including a PMOSFET region and an NMOSFET region, a pair of first channel patterns spaced apart in a first direction on the PMOSFET region, first source/drain patterns disposed at respective both sides of each of the first channel patterns in a second direction crossing the first direction, a first insulating structure disposed between a pair of the first source/drain patterns disposed at one side of the first channel patterns, a first gate pattern surrounding at least a portion of the first channel patterns, an etch stop layer disposed in the first direction between the first insulating structure and each of the pair of first source/drain patterns, a pair of second channel patterns spaced apart in the first direction on the NMOSFET region, second source/drain patterns disposed at respective both sides of each of the second channel patterns in the second direction, a second insulating structure disposed between a pair of the second source/drain patterns disposed at one side of the second channel patterns, and a second gate pattern surrounding at least a portion of the second channel patterns, wherein one side of each of the second source/drain patterns contacts the second insulating structure in the first direction.

According to some implementations, the present disclosure is directed to a semiconductor device comprising a substrate including a PMOSFET region and an NMOSFET region, a pair of first channel patterns spaced apart in a first direction on the PMOSFET region, first source/drain patterns disposed at respective both sides of each of the first channel patterns in a second direction crossing the first direction, a first gate pattern surrounding at least a portion of the first channel patterns, a pair of second channel patterns spaced apart in the first direction on the NMOSFET region, second source/drain patterns disposed at respective both sides of each of the second channel patterns in the second direction, a second gate pattern surrounding at least a portion of the second channel patterns, a first insulating structure disposed between a pair of the first source/drain patterns disposed at one side of the first channel patterns, and a second insulating structure disposed between a pair of the second source/drain patterns disposed at one side of the second channel patterns, wherein an upper level of the first insulating structure is lower than upper levels of the pair of first source/drain patterns, and an upper level of the second insulating structure is higher than upper levels of the pair of second source/drain patterns.

According to some implementations, the present disclosure is directed to a method of manufacturing a semiconductor device comprising forming a pair of first channel patterns spaced apart in a first direction, a first gate structure surrounding at least a portion of the first channel patterns, and a pair of first source/drain patterns connected to one side of the pair of first channel patterns and spaced apart in the first direction over a PMOSFET region of a substrate, and forming a pair of second channel patterns spaced apart in the first direction, a second gate structure surrounding at least a portion of the second channel patterns, and a pair of second source/drain patterns connected to one side of the pair of second channel patterns and spaced apart in the first direction over an NMOSFET region of the substrate. The method further comprises forming a first insulating structure between the pair of first source/drain patterns and forming a second insulating structure separating the pair of second source/drain patterns in the first direction.

According to some implementations, the present disclosure is directed to a method of manufacturing a semiconductor device comprising sequentially forming a first lower insulating structure and a first upper insulating structure between the pair of first source/drain patterns, and sequentially forming a second lower insulating structure and a second upper insulating structure between the pair of second source/drain patterns.

According to some implementations, the present disclosure is directed to a method of manufacturing a semiconductor device comprising forming an etch stop layer over the first lower insulating structure and the second lower insulating structure, and forming the first upper insulating structure and the second upper insulating structure over the etch stop layer.

According to some implementations, the etch stop layer is disposed between the first upper insulating structure and each of the pair of first source/drain patterns, and not disposed between the second upper insulating structure and each of the pair of second source/drain patterns.

According to some implementations, the etch stop layer may be disposed at both sides of the first upper insulating structure, and comprise a portion contacting one of the pair of first source/drain patterns and the first upper insulating structure.

According to some implementations, the etch stop layer may remain on at least a portion of sidewalls and a bottom surface of the first upper insulating structure after forming the first upper insulating structure.

According to some implementations, the present disclosure is directed to a method of manufacturing a semiconductor device comprising forming first and second contact plugs respectively connected to the first and second source/drain patterns.

According to some implementations, the second upper insulating structure may be formed to comprise a portion having a convex shape toward the second contact plug.

According to some implementations, the first upper insulating structure may be spaced apart from the first source/drain patterns in the first direction, and at least a portion of the second upper insulating structure may contact the second source/drain patterns.

According to some implementations, the reliability of a semiconductor device can be improved.

### BRIEF DESCRIPTION OF THE DRAWINGS

Example implementations will be more clearly understood from the following detailed explanation, taken in conjunction with the accompanying drawings.

FIG. 1 is a plan view illustrating an example of a semiconductor device according to some implementations.

FIG. 2 is a cross-sectional view taken along line A-A′ of FIG. 1 according to some implementations.

FIG. 3 is a cross-sectional view taken along line B-B′ of FIG. 1 according to some implementations.

FIG. 4 is a cross-sectional view taken along line C-C′ of FIG. 1 according to some implementations.

FIG. 5 is an enlarged view of regions M and N of FIG. 4 according to some implementations.

FIG. 6 is an enlarged view of regions M and N of FIG. 4 according to some implementations.

FIG. 7 is an enlarged view of region M of FIG. 4 according to some implementations.

FIG. 8 is an enlarged view of region N of FIG. 4 according to some implementations.

FIG. 9 is a cross-sectional view taken along line C-C′ of FIG. 1 according to some implementations.

FIG. 10 is a cross-sectional view taken along line C-C′ of FIG. 1 according to some implementations.

FIG. 11 is a plan view illustrating an example of a semiconductor device according to some implementations.

FIG. 12 is a cross-sectional view taken along line D-D′ of FIG. 11 according to some implementations.

FIG. 13 is a plan view illustrating an example of a semiconductor device according to some implementations.

FIG. 14 is a cross-sectional view taken along line E-E′ of FIG. 13 according to some implementations.

FIGS. 15 to 26 are cross-sectional views illustrating examples of intermediate steps of a method of manufacturing a semiconductor device according to some implementations.

FIGS. 27 to 29 are cross-sectional views illustrating examples of intermediate steps of a method of manufacturing a semiconductor device according to some implementations.

### DETAILED DESCRIPTION

Hereinafter, example implementations will be explained in detail with reference to the accompanying drawings.

In order to clearly explain implementations the present disclosure, parts irrelevant to the description are omitted, and the same reference numerals are used for identical or similar components throughout the present disclosure.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when a part, such as a layer, membrane, region, or plate, is described to be “over” or “on” another part, this includes not only cases where it is “directly over” the other part, but also cases where there are other parts in between. Conversely, when a part is described to be “directly above” another part, we mean that there is no other part in between. Also, being “above” or “on” a reference part means being disposed above or below the reference part, and does not necessarily mean being disposed “above” or “on” the opposite direction of gravity.

Additionally, throughout the present disclosure, whenever a part is described to “include” a component, this does not mean that it excludes other components, but rather that it may include other components, unless otherwise specifically stated.

Additionally, throughout the present disclosure, when it is described as “in plan”, the target portion is viewed from above, and when it is described as “in cross section”, the target portion is viewed from the side in a cross-section cut vertically.

Additionally, throughout the present disclosure, two directions parallel to and intersecting with the upper surface of the substrate are defined as a first direction D1 and a second direction D2, respectively, and the direction perpendicular to the upper surface of the substrate is described as a third direction D3. For example, the first direction D1 and the second direction D2 may be orthogonal to each other.

In the drawings relating to a semiconductor device according to some implementations, by way of example only, a transistor including nanowires or nanosheets, a Multi-Bridge Channel Field Effect Transistor (MBCFET™), and a fin-type transistor including a channel region in a fin-type pattern shape (FinFET) are illustrated, but the invention is not limited thereto. It should be noted that semiconductor devices according to some implementations may include tunneling FETs, 3D Stack Field Effect Transistors (3DSFETs), Complementary Field Effect Transistors (CFETs), and the like.

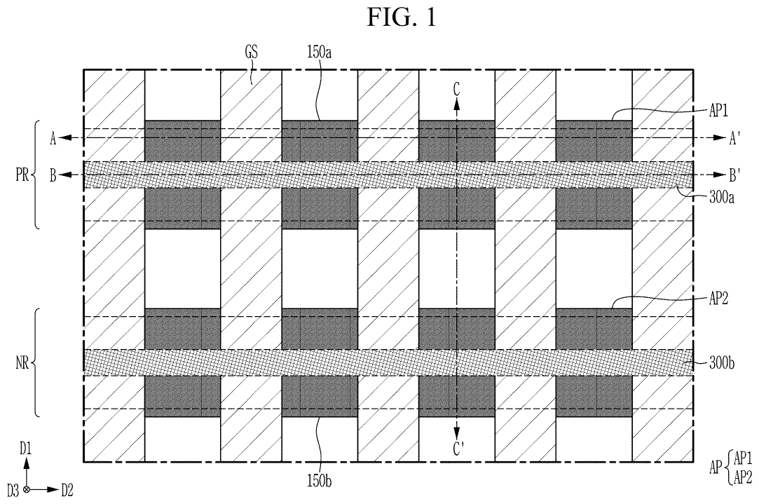

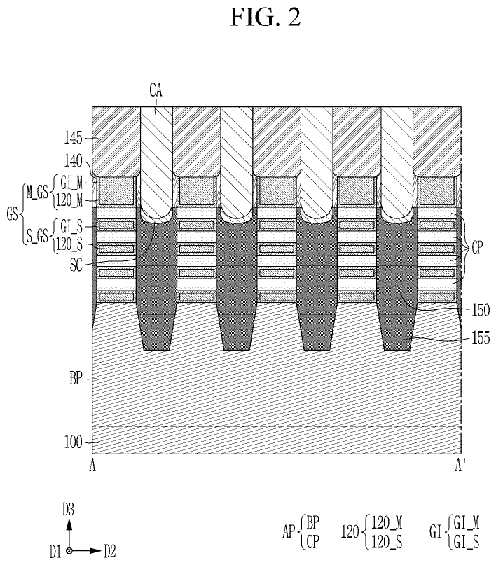

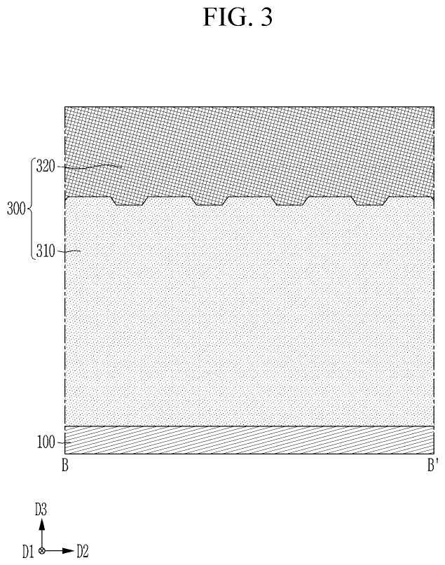

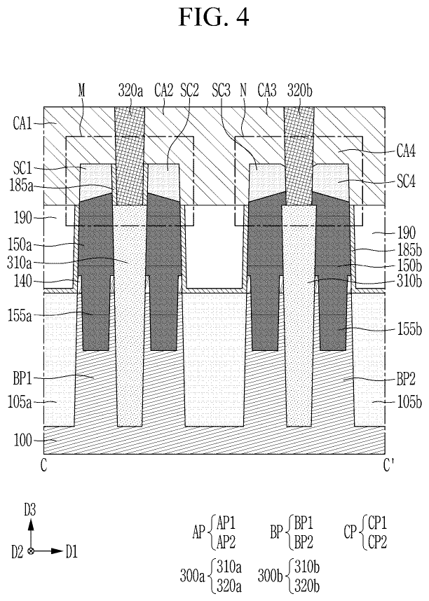

Hereinafter, a semiconductor device according to some implementations will be described with reference to the drawings. FIG. 1 is a plan view illustrating an example of a semiconductor device according to an some implementations. FIG. 2 is a cross-sectional view taken along line A-A′ of FIG. 1 according to some implementations. FIG. 3 is a cross-sectional view taken along line B-B′ of FIG. 1 according to some implementations. FIG. 4 is a cross-sectional view taken along line C-C′ of FIG. 1 according to some implementations.

In FIG. 1, a semiconductor device includes a gate structure GS, a first active pattern AP1, a second active pattern AP2, a first source/drain pattern 150a, a second source/drain pattern 150b, a first insulating structure 300a, and a second insulating structure 300b.

In FIGS. 1 to 4, the semiconductor device may include a substrate 100, channel patterns CP positioned on the substrate 100, source/drain patterns 150 positioned on both sides of each of the channel patterns CP, and a gate structure GS surrounding at least a portion of the channel patterns CP.

For example, the substrate 100 may be a semiconductor substrate including silicon, germanium, or silicon-germanium, or a compound semiconductor substrate. As another example, the substrate 100 may be an insulating substrate including an insulating material. The upper surface of the substrate 100 may be formed as a plane parallel to the first direction D1 and a second direction D2 intersecting the first direction D1.

According to some implementations, the substrate 100 may include a PMOSFET region PR and an NMOSFET region NR. A PMOSFET region PR and an NMOSFET region NR may be defined by a first active pattern AP1 and a second active pattern AP2 positioned on a substrate 100. In other words, the first active pattern AP1 and the second active pattern AP2 may be placed in the PMOSFET region PR and the NMOSFET region NR, respectively.

In FIGS. 1 to 4, the PMOSFET region PR may include first active patterns AP1 spaced apart in a first direction D1. The NMOSFET region NR may include second active patterns AP2 spaced apart in the first direction D1. The semiconductor device may include a first insulating structure 300a positioned between first active patterns AP1. The semiconductor device may include a second insulating structure 300b positioned between second active patterns AP2.

The active patterns AP may protrude from the substrate 100. The active patterns AP may be extended in the second direction D2. The active patterns AP may protrude in a third direction D3 from the upper surface of the substrate 100.

The first active patterns AP1 may be spaced apart from each other along the first direction D1. For example, first active patterns AP1 may be positioned on both sides of the first insulating structure 300a. The second active patterns AP2 may be spaced apart from each other along the first direction D1. For example, second active patterns AP2 may be positioned on both sides of the second insulating structure 300b.

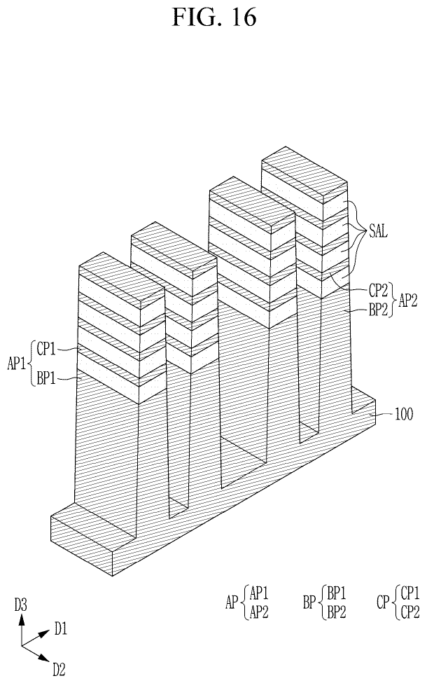

According to some implementations, the active patterns AP may be multi-channel active patterns. Each of the active patterns AP may include lower patterns BP and channel patterns CP. For example, the first active pattern AP1 may include a first lower pattern BP1 and a first channel pattern CP1. Additionally, for example, the second active pattern AP2 may include a second lower pattern BP2 and a second channel pattern CP2. For example, the lower patterns BP and the channel patterns CP may have a nanosheet shape and may be channel patterns including semiconductor materials. As described below with reference to FIG. 16, the channel pattern on the first lower pattern BP1 will be referred to as the first channel pattern CP1, and the channel pattern on the second lower pattern BP2 will be referred to as the second channel pattern CP2.

The lower patterns BP may be positioned on the substrate 100. The lower patterns BP may protrude from the substrate 100. The lower patterns BP may extend in the second direction D2.

The channel patterns CP may be positioned on the upper surface of the lower patterns BP. For example, the first channel patterns CP1 may be positioned on the upper surface of the first lower pattern BP1, and the second channel patterns CP2 may be positioned on the upper surface of the second lower pattern BP2.

The channel patterns CP may be spaced apart from the lower patterns BP in a third direction D3. Channel patterns CP spaced apart from each other in a third direction D3 may be positioned on one lower pattern BP. For example, first channel patterns CP1 spaced apart from each other in a third direction D3 may be positioned on a first lower pattern BP1, and second channel patterns CP2 spaced apart from each other in a third direction D3 may be positioned on a second lower pattern BP2.

Here, the third direction D3 may be a direction intersecting the second direction D2 and the first direction D1. For example, the third direction D3 may be the thickness direction of the substrate 100. The first direction D1 may be a direction intersecting the second direction D2.

The channel patterns CP may be separated in a first direction D1 by an insulating structure 300 described below. For example, although not clearly shown, a first insulating structure 300a may be positioned between first channel patterns CP1 positioned adjacent to each other in the first direction D1. Additionally, for example, a second insulating structure 300b may be positioned between second channel patterns CP2 positioned adjacent to each other in the first direction D1.

In FIG. 2, four channel patterns CP are illustrated as being spaced apart and stacked along the third direction D3, but this is only for convenience of explanation and the present disclosure is not limited thereto. For example, two or three channel patterns CP may be stacked spaced apart along the third direction D3, or five or more channel patterns CP may be stacked spaced apart along the third direction D3.

According to some implementations, the lower patterns BP may be formed by etching a portion of the substrate 100 and may include an epitaxial layer grown from the substrate 100. The lower patterns BP may contain elemental semiconductor materials such as silicon (Si) or germanium (Ge). Additionally, the lower patterns BP may include a compound semiconductor, for example, a group IV-IV compound semiconductor or a group III-V compound semiconductor.

The IV-IV group compound semiconductor may be, for example, a binary compound or ternary compound containing at least two or more of carbon (C), silicon (Si), germanium (Ge), and tin (Sn).

The III-V group compound semiconductor may be, for example, a binary compound, a ternary compound, or a quaternary compound formed by combining at least one of aluminum (Al), gallium (Ga), and indium (In), which are group III elements, with one of phosphorus (P), arsenic (As), and antimonium (Sb), which are group V elements.

However, the present disclosure is not limited to the above, and in some cases, the lower pattern BP may be formed of an insulating pattern including an insulating material.

According to some implementations, the channel patterns CP may include one of the elemental semiconductor materials, silicon (Si) or silicon germanium (SiGe), a group IV-IV compound semiconductor, or a group III-V compound semiconductor. Each channel pattern CP may contain the same material as the lower patterns BP or may contain a different material from the lower patterns BP.

In a semiconductor device according to some implementations, the lower patterns BP may be silicon lower patterns including silicon (Si), and the channel patterns CP may be silicon sheet patterns including silicon (Si). In some implementations, the lower patterns BP may be insulating patterns including an insulating material, and the channel patterns CP may be silicon sheet patterns including silicon (Si).

In some implementations, a semiconductor device may further include first and second field insulating layers 105a and 105b positioned on a substrate 100.

In FIG. 4, the first field insulating layer 105a may be disposed in the PMOSFET region PR. The first field insulating layer 105a may be positioned on the side surfaces of the first lower patterns BP1. The first field insulating layer 105a may not be disposed on the upper surface of the first lower patterns BP1. The first field insulating layer 105a may cover a portion of the side surfaces of the first lower patterns BP1, but the present disclosure is not limited thereto. For example, the first field insulating layer 105a may completely cover the side surfaces of the first lower patterns BP1. The channel patterns CP may be positioned higher than the upper surface of the first field insulating layer 105a.

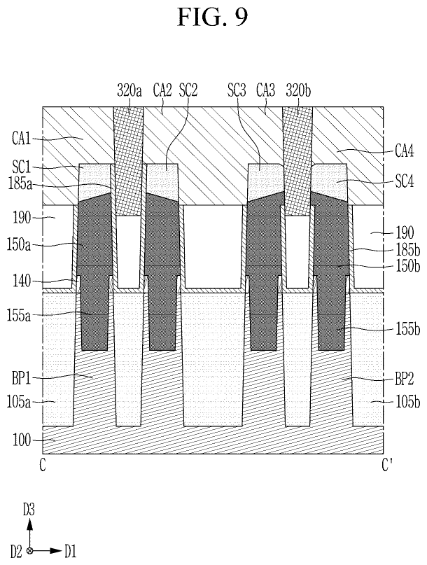

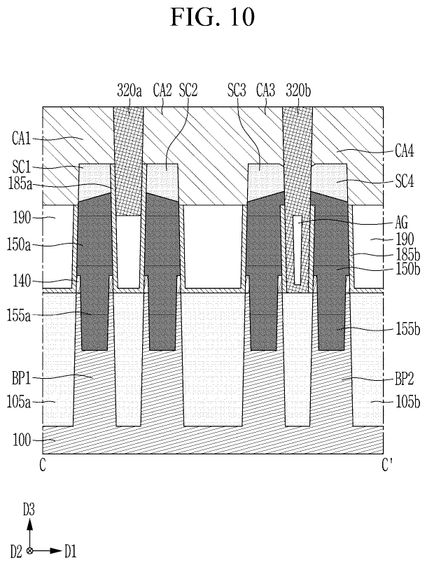

In FIG. 4, a first lower insulating structure 310a described later is positioned between first lower patterns BP1 positioned adjacent to each other in the first direction D1, but as shown in FIG. 9 and FIG. 10 below, a first field insulating layer 105a may also be positioned between first lower patterns BP1 positioned adjacent to each other in the first direction D1.

The second field insulating layer 105b may be disposed in the NMOSFET region NR. The second field insulating layer 105b may be positioned on the side surfaces of the second lower patterns BP2. The second field insulating layer 105b may not be disposed on the upper surface of the second lower patterns BP2. The second field insulating layer 105b may cover a portion of the side surfaces of the second lower patterns BP2, but the present disclosure is not limited thereto. For example, the second field insulating layer 105b may completely cover the side surfaces of the second lower patterns BP2. The channel patterns CP may be positioned higher than the upper surface of the second field insulating layer 105b.

In FIG. 4, a second lower insulating structure 310b described later is positioned between second lower patterns BP2 positioned adjacent to each other in the first direction D1, but as shown in FIG. 9 and FIG. 10 below, a second field insulating layer 105b may also be positioned between second lower patterns BP2 positioned adjacent to each other in the first direction D1.

The first and second field insulating layers 105a and 105b may include various insulating materials. For example, the first and second field insulating layers 105a and 105b may include, but are not limited to, silicon oxide (SiO₂). As another example, the first and second field insulating layers 105a and 105b may include silicon nitride (SiN), silicon oxynitride (SiON), or a combination thereof. The first and second field insulating layers 105a and 105b are illustrated as single layer, but this is only for convenience of explanation and the present disclosure is not limited thereto.

A semiconductor device may further include an insulating structure 300 positioned on a substrate 100. In the present disclosure, the insulating structure 300 may include a first insulating structure 300a disposed in a PMOSFET region PR and a second insulating structure 300b disposed in an NMOSFET region NR. Additionally, in the present disclosure, the lower insulating structure 310 may include a first lower insulating structure 310a disposed in the PMOSFET region PR and a second lower insulating structure 310b disposed in the NMOSFET region NR. Additionally, in the present disclosure, the upper insulating structure 320 may include a first upper insulating structure 320a disposed in the PMOSFET region PR and a second upper insulating structure 320b disposed in the NMOSFET region NR.

The first insulating structure 300a may be disposed in the PMOSFET region PR. In some implementations, the first insulating structure 300a may be positioned between side surfaces of the first source/drain patterns 150a on the substrate 100. For example, as illustrated in FIG. 4, the first insulating structure 300a may be positioned between first source/drain patterns 150a positioned adjacent to each other in the first direction D1.

The second insulating structure 300b may be disposed in the NMOSFET region NR. According to some implementations, the second insulating structure 300b may be positioned between side surfaces of the second source/drain patterns 150b on the substrate 100. For example, as illustrated in FIG. 4, the second insulating structure 300b may be positioned between second source/drain patterns 150b positioned adjacent to each other in the first direction D1.

Meanwhile, the insulating structure 300 may overlap with the channel patterns CP in the first direction D1. The insulating structure 300 may be in contact with the side of the gate structure GS. For example, the insulating structure 300 may be in contact with a gate insulating layer GI surrounding the channel patterns CP. Additionally, for example, the insulating structure 300 may be in contact with a side surface of a gate pattern 120 positioned between adjacent channel patterns CP in the third direction D3.

In FIGS. 3 and 4, an insulating structure 300 may include a lower insulating structure 310 extending in a second direction D2 on a substrate 100 and an upper insulating structure 320 positioned on the lower insulating structure 310.

In FIGS. 1 and 4, the first upper insulating structure 320a may extend in the second direction D2. In other words, the first upper insulating structure 320a may be positioned not only between a pair of first source/drain patterns 150a spaced apart from each other in the first direction D1, but also between a pair of first active patterns AP1 spaced apart from each other in the first direction D1. According to some implementations, the second upper insulating structure 320b may extend in the second direction D2. In other words, the second upper insulating structure 320b may be positioned not only between a pair of second source/drain patterns 150b spaced apart from each other in the first direction D1, but also between a pair of second active patterns AP2 spaced apart from each other in the first direction D1.

The lower level of the upper insulating structure 320 along the second direction D2 may not be constant. In other words, the lower level of the upper insulating structure 320 along the second direction D2 may be irregular and uneven.

Specifically, the first upper insulating structure 320a positioned between the first active patterns AP1 may have a lower level higher than the first upper insulating structure 320a positioned between the first source/drain patterns 150a. According to some implementations, the second upper insulating structure 320b positioned between the second active patterns AP2 may have a lower level higher than the second upper insulating structure 320b positioned between the second source/drain patterns 150b.

According to some implementations, a first upper insulating structure 320a is positioned between a first contact plug CA1 and a second contact plug CA2 described below, and may be positioned between at least a portion of a pair of first source/drain patterns 150a. The second upper insulating structure 320b is positioned between the third contact plug CA3 and the fourth contact plug CA4 described below and may be positioned between at least a portion of a pair of second source/drain patterns 150b.

The upper surface of the first upper insulating structure 320a may be positioned at a higher level than the upper surface of the first source/drain pattern 150a. In other words, the upper surface of the first upper insulating structure 320a may be positioned further from the upper surface of the substrate 100 than the upper surface of the first source/drain pattern 150a. In other words, the first upper insulating structure 320a may protrude in the third direction D3 more than the first source/drain pattern 150a.

The upper surface of the second upper insulating structure 320b may be positioned at a higher level than the upper surface of the second source/drain pattern 150b. In other words, the upper surface of the second upper insulating structure 320b may be positioned further from the upper surface of the substrate 100 than the upper surface of the second source/drain pattern 150b. In other words, the second upper insulating structure 320b may protrude in the third direction D3 more than the second source/drain pattern 150b.

The upper surface of the first upper insulating structure 320a may be positioned at substantially the same level as the upper surfaces of the first contact plug CA1 and the second contact plug CA2 described later. In other words, the distance from the upper surface of the substrate 100 to the upper surface of the first upper insulating structure 320a may be substantially equal to the distance from the upper surface of the substrate 100 to the upper surfaces of the first contact plug CA1 and the second contact plug CA2.

Accordingly, the first contact plug CA1 and the second contact plug CA2 may be separated from each other along the first direction D1 based on the first upper insulating structure 320a. In other words, the first contact plug CA1 disposed on one side of the first upper insulating structure 320a along the first direction D1 and the second contact plug CA2 disposed on the other side of the first upper insulating structure 320a along the first direction D1 may be separated from each other. In other words, the first upper insulating structure 320a may insulate between the first contact plug CA1 and the second contact plug CA2.

The upper surface of the second upper insulating structure 320b may be positioned at substantially the same level as the upper surfaces of the third contact plug CA3 and the fourth contact plug CA4 described later. In other words, the distance from the upper surface of the substrate 100 to the upper surface of the second upper insulating structure 320b may be substantially equal to the distance from the upper surface of the substrate 100 to the upper surfaces of the third contact plug CA3 and the fourth contact plug CA4.

Accordingly, the third contact plug CA3 and the fourth contact plug CA4 may be separated from each other along the first direction D1 based on the second upper insulating structure 320b. In other words, the third contact plug CA3 disposed on one side of the second upper insulating structure 320b along the first direction D1 and the fourth contact plug CA4 disposed on the other side of the second upper insulating structure 320b along the first direction D1 may be separated from each other. In other words, the second upper insulating structure 320b may insulate between the third contact plug CA3 and the fourth contact plug CA4.

The first lower insulating structure 310a may be positioned below the first upper insulating structure 320a. According to some implementations, the first lower insulating structure 310a may extend in a third direction D3 between a pair of first source/drain patterns 150a. The lower level of the first lower insulating structure 310a may be substantially identical to the upper level of the substrate 100. However, the present disclosure is not limited thereto, and the lower level of the first lower insulating structure 310a may be higher than the upper level of the substrate 100.

The second lower insulating structure 310b may be positioned below the second upper insulating structure 320b. According to some implementations, the second lower insulating structure 310b may extend in a third direction D3 between a pair of second source/drain patterns 150b. The lower level of the second lower insulating structure 310b may be substantially identical to the upper level of the substrate 100. However, the present disclosure is not limited thereto, and the lower level of the second lower insulating structure 310b may be higher than the upper level of the substrate 100.

According to some implementations, the first lower insulating structure 310a and the second lower insulating structure 310b may separate and space the gate pattern 120 extending in the first direction D1 in the PMOSFET region PR and the NMOSFET region NR, respectively.

The gate patterns 120 of the PMOSFET region PR may be separated from each other along the first direction D1 with respect to the first lower insulating structure 310a. In other words, the gate pattern 120 disposed on one side of the first lower insulating structure 310a along the first direction D1 and the gate pattern 120 disposed on the other side of the first lower insulating structure 310a along the first direction D1 may be separated from each other.

The gate pattern 120 of the NMOSFET region NR may be separated from each other along the first direction D1 with respect to the second lower insulating structure 310b. In other words, the gate pattern 120 disposed on one side of the second lower insulating structure 310b along the first direction D1 and the gate pattern 120 disposed on the other side of the second lower insulating structure 310b along the first direction D1 may be separated from each other.

The first lower insulating structure 310a and the second lower insulating structure 310b may insulate between the gate patterns 120.

The insulating structure 300 may include an insulating material. For example, the insulating structure 300 may include, but is not limited to, silicon oxide (SiO₂), and may also include silicon nitride (SiON), silicon carbonitride (SiOCN), silicon oxycarbide (SiOC), or a combination thereof.

The upper insulating structure 320 and the lower insulating structure 310 may comprise the same material. The boundary between the upper insulating structure 320 and the lower insulating structure 310 may not be recognized. However, the present disclosure is not limited to the above, and the upper insulating structure 320 and the lower insulating structure 310 may include different materials.

In FIGS. 1 and 2, a gate structure GS may be positioned on a substrate 100. The gate structure GS may extend between the insulating structures 300 in the first direction D1. The gate structures GS may be arranged spaced apart in the second direction D2.

The gate structure GS may cross the active patterns AP in the plane. In other words, the gate structure GS may intersect the active patterns AP in the plane.

The gate structure GS surround at least a portion of the channel patterns CP. For example, the gate structure GS may cover one side, bottom surface, and top surface of the first channel patterns CP1, and may cover one side, bottom surface, and top surface of the second channel patterns CP2. Additionally, the gate structure GS may surround at least a portion of the insulating structure 300. In other words, the gate structure GS may surround at least a portion of the channel patterns CP and the insulating structure 300. Accordingly, one side, bottom surface, and top surface of the channel patterns CP may each be in contact with the gate structure GS.

The gate structure GS may include a plurality of sub-gate structures S_GS and a main gate structure M_GS. The gate structure GS may include a gate pattern 120 and a gate insulating layer GI. In the present disclosure, the gate pattern 120 may be defined as a concept including a main gate pattern 120_M and a sub gate pattern 120_S. Additionally, the gate insulating layer GI may include a main gate insulating layer GI_M and a sub gate insulating layer GI_S.

The gate pattern 120 may be positioned on the lower pattern BP. The gate pattern 120 may surround at least a portion of each of the channel patterns CP.

According to some implementations, at least a portion of the gate pattern 120 may be positioned on a stacked structure of a sub-gate pattern 120_S and a plurality of channel patterns CP. Additionally, another portion of the gate pattern 120 may be formed to cover one side of the stacked structure of the sub-gate pattern 120_S and the plurality of channel patterns CP. At this time, three surfaces of the plurality of channel patterns CP may be surrounded by a gate pattern 120.

The gate pattern 120 may be a multilayer structure including at least one work function layer and a metal filling layer. For example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbon nitride (TaCN), or tantalum carbide (TaC). For example, the metal filler layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or combinations thereof. However, the present disclosure is not limited thereto, and the gate pattern 120 may be composed of a single layer.

According to some implementations, a plurality of sub-gate structures S_GS may be positioned between a plurality of adjacent channel patterns CP in the third direction D3 and between a lower pattern BP and a channel pattern CP disposed at the lowermost position. The main gate structure M_GS may be positioned on the channel pattern CP disposed at the top.

Specifically, a plurality of sub-gate structures S_GS may be positioned between the upper surfaces of the lower patterns BP and the lower surface of the lowermost channel pattern CP, and between the upper surfaces of the channel patterns CP and the lower surfaces of the channel patterns CP facing each other in the third direction D3. A plurality of sub-gate structures S_GS may be adjacent to the source/drain patterns 150 described below in the second direction D2. The main gate structure M_GS may be positioned on the upper surface of a plurality of sub-gate structures S_GS and channel patterns CP.

According to some implementations, the number of the plurality of sub-gate structures S_GS may be proportional to the number of the plurality of channel patterns CP stacked along the third direction D3. For example, the number of the plurality of sub-gate structures S_GS may be equal to the number of the plurality of channel patterns CP. For example, as illustrated in FIG. 2, the number of the plurality of sub-gate structures S_GS may be four. However, the present disclosure is not limited thereto, and the plurality of sub-gate structures S_GS may include three or five or more sub-gate structures S_GS.

According to some implementations, each of the plurality of sub-gate structures S_GS may include a sub-gate pattern 120_S and a sub-gate insulating layer GI_S. The sub-gate pattern 120_S may be formed on the lower pattern BP. The sub-gate pattern 120_S may intersect with the lower pattern BP. The sub-gate pattern 120_S may surround at least a portion of each of the plurality of channel patterns CP.

For example, the sub-gate pattern 120_S may include at least one of a metal, a metal alloy, a conductive metal nitride, a metal silicide, a doped semiconductor material, a conductive metal oxide, and a conductive metal nitride. The sub-gate pattern 120_S may be, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), It may include at least one of, but is not limited to, molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal nitrides may include, but are not limited to, oxidized forms of the materials described above.

The sub-gate insulating layer GI_S may extend along the upper surface of the lower pattern BP. A sub-gate insulating layer GI_S may be positioned along the perimeter of a plurality of channel patterns CP. The sub-gate insulating layer GI_S may be in direct contact with the lower pattern BP and the plurality of channel patterns CP. A sub-gate insulating layer GI_S may be interposed between a plurality of channel patterns CP and a sub-gate pattern 120_S. Additionally, the sub-gate insulating layer GI_S may extend along the upper surfaces of the first and second field insulating layers 105a and 105b.

Meanwhile, an inner spacer may be interposed between the plurality of sub-gate patterns 120_S and the source/drain pattern 150. The inner spacer may contact the source/drain pattern 150. A plurality of sub-gate patterns 120_S may be spaced apart from the source/drain pattern 150 by inner spacers.

In the present disclosure, the sub-gate insulating layer GI_S is illustrated as a single layer, but the present disclosure is not limited thereto, and the sub-gate insulating layer GI_S may be formed of the plurality of layers.

According to some implementations, a main gate structure M_GS may be positioned on a sub-gate structure S_GS and a plurality of channel patterns CP. The main gate structure M_GS may be positioned on the upper surface of a channel pattern disposed at the uppermost position among a plurality of channel patterns CP.

The main gate structure M_GS may include a main gate pattern 120_M and a main gate insulating layer GI_M.

The main gate pattern 120_M may be positioned on a sub-gate structure S_GS and a plurality of channel patterns CP. The main gate pattern 120_M may be positioned on the upper surface of the channel pattern disposed at the uppermost position among the plurality of channel patterns CP. The main gate pattern 120_M may be disposed between the gate spacers 140 described later.

The main gate pattern 120_M may include the same material as the sub-gate pattern 120_S. For example, the main gate pattern 120_M may include at least one of a metal, a metal alloy, a conductive metal nitride, a metal silicide, a doped semiconductor material, a conductive metal oxide, and a conductive metal nitride.

The main gate insulating layer GI_M may extend along the side and bottom surfaces of the main gate pattern 120_M. The main gate insulating layer GI_M may extend along the side of the gate spacer 140 to be described later.

The main gate insulating layer GI_M may be formed integrally with the sub-gate insulating layer GI_S in the same process. The main gate insulating layer GI_M may be formed integrally with the sub gate insulating layer GI_S.

For example, the main gate insulating layer GI_M may include silicon oxide, silicon oxynitride, or silicon nitride. In some implementations, the main gate insulating layer GI_M may include a high-k material. Or, for example, the main gate insulating layer GI_M may include both silicon oxide and a high-k material.

The main gate insulating layer GI_M is illustrated as a single layer, but the present disclosure is not limited thereto, and the main gate insulating layer GI_M may be formed of the plurality of layers.

The sub-gate pattern 120_S and the main gate pattern 120_M may constitute a gate pattern 120 of a semiconductor device. Additionally, the sub-gate insulating layer GI_S and the main gate insulating layer GI_M may constitute a gate insulating layer GI of a semiconductor device.

In other words, a portion of a gate pattern 120 included in a plurality of sub-gate structures S_GS may be referred to as a sub-gate pattern 120_S, and a portion of a gate insulating layer GI included in a plurality of sub-gate structures S_GS may be referred to as a sub-gate insulating layer GI_S. Additionally, a portion of the gate pattern 120 included in the main gate structure M_GS may be referred to as a main gate pattern 120_M, and a portion of the gate insulating layer GI included in the main gate structure M_GS may be referred to as a main gate insulating layer GI_M.

A semiconductor device may further include a gate spacer 140. The gate spacer 140 may be disposed on both sides of the main gate pattern 120_M. The gate spacer 140 may be disposed on the outside of the main gate insulating layer GI_M. A main gate insulating layer GI_M may be positioned between the main gate pattern 120_M and the gate spacer 140. The gate spacer 140 may not be disposed between the main gate pattern 120_M and the channel pattern CP.

The gate spacer 140 may include at least one of, for example, silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and combinations thereof. The gate spacer 140 is illustrated as a single layer, but the present disclosure is only for convenience of explanation and is not limited thereto, and may be formed of a multi-layer.

A semiconductor device may further include a capping layer 145 positioned on the gate structure GS. The capping layer 145 may be positioned on the gate structure GS and the gate spacer 140. In some implementations, the capping layer 145 may be disposed between the gate spacers 140. The capping layer 145 may include, for example, at least one of silicon nitride (SiN), silicon oxynitride (SiON), silicon carbon nitride (SiCN), silicon carbonate nitride (SiOCN), and combinations thereof. The capping layer 145 may include a material having an etching selectivity with respect to the interlayer insulating layer 190 described later.

The source/drain patterns 150 may be positioned on the lower patterns BP. For example, as illustrated in FIG. 4, the first source/drain patterns 150a may be positioned above each of the first lower patterns BP1. According to some implementations, the first source/drain patterns 150a positioned on the first lower pattern BP1 may be spaced apart from each other. In other words, the first source/drain patterns 150a positioned above each of the first lower patterns BP1 may not contact each other.

Additionally, for example, as illustrated in FIG. 4, the second source/drain patterns 150b may be positioned above each of the second lower patterns BP2. According to some implementations, the second source/drain patterns 150b positioned on the second lower pattern BP2 may be spaced apart from each other. In other words, the second source/drain patterns 150b positioned above each of the second lower patterns BP2 may not contact each other.

The source/drain pattern 150 may be disposed on both sides of the sub-gate structure S_GS. For example, the source/drain pattern 150 may be disposed on both sides of the sub-gate structure S_GS along the second direction D2. Additionally, the source/drain patterns 150 may be disposed on both sides of the channel patterns CP along the second direction D2. The source/drain pattern 150 may be electrically connected to the channel patterns CP.

The source/drain pattern 150 may be positioned within a source/drain recess having a depth along the third direction D3. The source/drain pattern 150 may fill the source/drain recess. The bottom surface of the source/drain recess may be defined by lower patterns BP. The sides of the source/drain recesses may be defined by channel patterns CP and sub-gate structures S_GS. However, semiconductor devices may include inner spacers, wherein the sides of the source/drain recesses may be defined by channel patterns CP and the inner spacers.

The outer surface of the source/drain pattern 150 may be in contact with the channel patterns CP and the sub-gate structure S_GS. In some implementations, the outer surface of the source/drain pattern 150 may be formed as an uneven curved surface. For example, a portion of the outer surface of the source/drain pattern 150 that comes into contact with the channel patterns CP may have a concave or approximately flat shape in cross section, but the present disclosure is not limited thereto.

The source/drain patterns 150 may be epitaxial patterns formed by a selective epitaxial growth process using the active pattern AP as a seed. The source/drain pattern 150 may include at least one of silicon (Si) and silicon germanium (SiGe). The plurality of channel patterns CP may be part of an active pattern AP extending between the source/drain patterns 150. The source/drain pattern 150 may serve as the source/drain of a transistor that uses a plurality of channel patterns CP as a channel region.

The source/drain pattern 150 may include a first source/drain layer and a second source/drain layer. The first source/drain layer may have a shape that surrounds the side and lower surfaces of the second source/drain layer. A plurality of channel patterns CP may be in contact with the first source/drain layer and may not be in contact with the second source/drain layer. Accordingly, a first source/drain layer may be positioned between the plurality of channel patterns CP and the second source/drain layer.

However, the present disclosure is not limited to the above, and at least some of the plurality of channel patterns CP may be in contact with the second source/drain layer. Additionally, the source/drain pattern 150 may be formed as a single layer without being divided into a first source/drain layer and a second source/drain layer.

The lower surface of the source/drain pattern 150 may be disposed at a lower level than the lower surface of the sub-gate structure S_GS. For example, the lower surface of the source/drain pattern 150 may be positioned closer to the bottom surface of the lower pattern BP than the lower surface of the sub-gate structure S_GS disposed at the lowest position.

The semiconductor device may further include a dummy source/drain pattern 155 positioned beneath the source/drain pattern 150. For example, a first dummy source/drain pattern 155a may be positioned under a first source/drain pattern 150a, and a second dummy source/drain pattern 155b may be positioned under a second source/drain pattern 150b.

The dummy source/drain pattern 155 may be embedded within the lower pattern BP. dummy source/drain pattern 155 may be positioned below at least one source/drain pattern 150 among a plurality of source/drain patterns 150.

For example, the dummy source/drain pattern 155 may include the same material as the source/drain pattern 150. For example, the dummy source/drain pattern 155 may include silicon (Si) or silicon germanium (SiGe), and may further include carbon (C), silicon (Si), germanium (Ge), or tin (Sn).

A semiconductor device may further include first and second etch stop layers 185a and 185b positioned between an interlayer insulating layer 190 and a source/drain pattern 150, which will be described later.

In FIG. 4, the first and second etch stop layers 185a and 185b may extend along the upper surfaces of the first and second field insulating layers 105a and 105b. For example, the first etch stop layer 185a disposed in the PMOSFET region PR may extend along the upper surface of the first field insulating layer 105a. Additionally, for example, the second etch stop layer 185b disposed in the NMOSFET region NR may extend along the upper surface of the second field insulating layer 105b.

The first and second etch stop layers 185a and 185b may include a material having an etch selectivity with respect to the interlayer insulating layer 190. Additionally, the first and second etch stop layers 185a and 185b may include a material having an etching selectivity with respect to the source/drain pattern 150. The first and second etch stop layers 185a and 185b may include, for example, at least one of silicon nitride (SiN), silicon oxynitride (SiON), silicon carbonate (SiOCN), silicon boron nitride (SiBN), silicon oxyboron nitride (SiOBN), silicon oxycarbide (SiOC), and combinations thereof.

The first etch stop layer 185a may surround at least a portion of the first source/drain pattern 150a. According to some implementations, the first etch stop layer 185a may be positioned between the first source/drain pattern 150a and at least a portion of the first upper insulating structure 320a.

The second etch stop layer 185b may surround at least a portion of the second source/drain pattern 150b. According to some implementations, the second etch stop layer 185b may not be disposed between the second source/drain pattern 150b and the second upper insulating structure 320b.

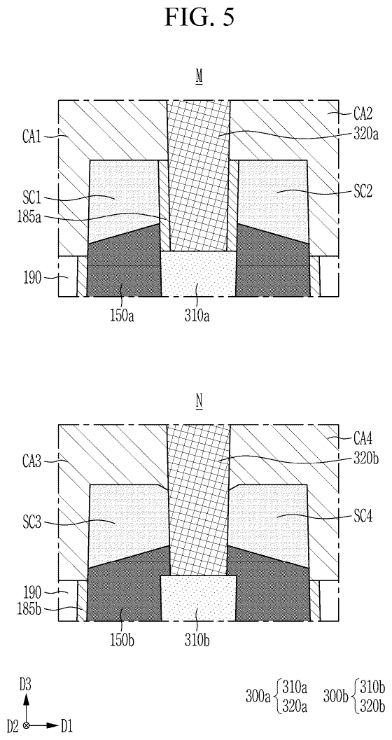

Details regarding the specific shape and position of the etch stop layer are described in detail later with reference to FIG. 5 to FIG. 8.

A semiconductor device may further include an interlayer insulating layer 190. An interlayer insulating layer 190 may be positioned between the first source/drain pattern 150a and the second source/drain pattern 150b. Specifically, as illustrated in FIG. 4, the interlayer insulating layer 190 may be positioned between the side surface of the first source/drain pattern 150a and the side surface of the second source/drain pattern 150b.

The interlayer insulating layer 190 may include, for example, at least one of silicon oxide (SiO₂), silicon nitride (SiN), silicon oxynitride (SiON), and a low-k material. Low-k materials include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), and TriMethylSiloxane (HMDS). Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Oxide), OSG (Organo) Silicate Glass), SiLK, Amorphous Fluorinated Carbon, silica aerogels, silica xerogels, may include, but is not limited to, mesoporous silica or combinations thereof.

According to some implementations, the semiconductor device may further include a contact plug CA positioned on the source/drain pattern 150. For example, the contact plug CA may be positioned between gate spacers 140 spaced apart in the second direction D2. In FIG. 2, the side of the contact plug CA is illustrated as being in contact with the gate spacer 140, but the present disclosure is not limited to the case, and the side of the contact plug CA may not be in direct contact with the gate spacer 140. According to some implementations, the contact plug CA may extend in a third direction D3. For example, a contact plug CA may extend in a third direction D3 between adjacent gate spacers 140 in a second direction D2.

According to some implementations, a silicide pattern SC may be positioned between a contact plug CA and a source/drain pattern 150. In a cross-section along the second direction D2 and the third direction D3, the silicide pattern SC may surround the bottom surface of the contact plug CA. Specifically, the silicide pattern SC may surround a portion of a contact plug CA inserted into the source/drain pattern 150.

The contact plug CA may include a conductive material. For example, the contact plug CA may include at least one of a metal, a metal alloy, a conductive metal nitride, a conductive metal carbide, a conductive metal oxide, a conductive metal carbonitride, and a two-dimensional (2D) material.

The silicide pattern SC may include a metal-silicide. For example, the silicide pattern SC may include at least one of titanium-silicide, tantalum-silicide, tungsten-silicide, nickel-silicide, and cobalt-silicide.

According to some implementations, a first contact plug CA1 and a second contact plug CA2 may be positioned on each of a pair of first source/drain patterns 150a spaced apart in a first direction D1. The first contact plug CA1 and the second contact plug CA2 may be separated from each other in the first direction D1 by the first upper insulating structure 320a.

According to some implementations, a third contact plug CA3 and a fourth contact plug CA4 may be positioned on each of a pair of second source/drain patterns 150b spaced apart in the first direction D1. The third contact plug CA3 and the fourth contact plug CA4 may be separated from each other in the first direction D1 by the second upper insulating structure 320b.

The second contact plug CA2 and the third contact plug CA3 may be connected to each other. However, the present disclosure is not limited thereto, and in some implementations, the second contact plug CA2 and the third contact plug CA3 may be separated from each other. For example, a third insulating structure may be positioned between the second contact plug CA2 and the third contact plug CA3, and the third insulating structure may insulate between the second contact plug CA2 and the third contact plug CA3.

The first contact plug CA1 and the second contact plug CA2 may be inserted inwardly from the upper surface of the first source/drain patterns 150a and connected to the first source/drain patterns 150a. The first contact plug CA1 and the second contact plug CA2 may be electrically connected to the first source/drain patterns 150a.

The third contact plug CA3 and the fourth contact plug CA4 may be inserted inwardly from the upper surface of the second source/drain patterns 150b and connected to the second source/drain patterns 150b. The third contact plug CA3 and the fourth contact plug CA4 may be electrically connected to the second source/drain patterns 150b.

According to some implementations, a first silicide pattern SC1 and a second silicide pattern SC2 may be positioned between the first contact plug CA1 and the second contact plug CA2 and the first source/drain patterns 150a, respectively.

According to some implementations, a third silicide pattern SC3 and a fourth silicide pattern SC4 may be positioned between the third contact plug CA3 and the fourth contact plug CA4 and the second source/drain patterns 150b, respectively.

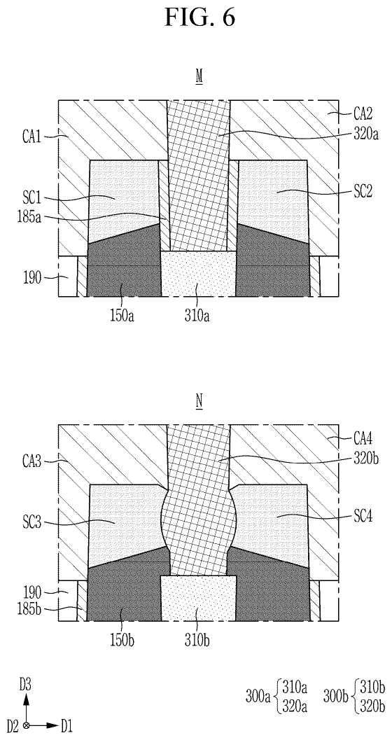

FIG. 5 is an enlarged view of regions M and N of FIG. 4 according to some implementations. FIG. 6 is an enlarged view of regions M and N of FIG. 4 according to some implementations.

In FIGS. 5 and 6, the M region and the N region correspond to the PMOSFET region PR and the NMOSFET region NR of the semiconductor device according to some implementations, respectively.

The PMOS transistor included in the PMOSFET region PR and the NMOS transistor included in the NMOSFET region NR may have generally similar structures. However, as described below, the shape and/or position of the first etch stop layer 185a disposed in the PMOSFET region PR and the shape and/or position of the second etch stop layer 185b disposed in the NMOSFET region NR may be different from each other. Additionally, the shape of the first source/drain pattern 150a included in the PMOS transistor and the shape of the second source/drain pattern 150b included in the NMOS transistor may be different from each other.

In FIGS. 5 and 6, the first upper insulating structure 320a positioned in the PMOSFET region PR may be spaced apart from the first source/drain pattern 150a in the first direction D1. According to some implementations, a first etch stop layer 185a may be positioned between the first upper insulating structure 320a and the first source/drain pattern 150a.

The first etch stop layer 185a may be positioned on both sides of the first upper insulating structure 320a. For example, the first etch stop layer 185a may be positioned on both sides of the first upper insulating structure 320a along the first direction D1. The first etch stop layer 185a may be disposed on both sides of a portion of the first upper insulating structure 320a. The upper level of the first etch stop layer 185a may be lower than the upper level of the first upper insulating structure 320a. The lower level of the first etch stop layer 185a may be substantially identical to the lower level of the first upper insulating structure 320a.

The first etch stop layer 185a may include a portion where one side is in contact with the first source/drain pattern 150a and the other side is in contact with the first upper insulating structure 320a. In other words, at least one side of the first etch stop layer 185a may be in contact with the first source/drain pattern 150a and the other side may be in contact with the first upper insulating structure 320a.

According to some implementations, at least a portion of the first etch stop layer 185a positioned on one side of the first upper insulating structure 320a may be positioned between the first upper insulating structure 320a and the first source/drain pattern 150a, and another portion of the first etch stop layer 185a may be positioned between the first upper insulating structure 320a and the first silicide pattern SC1. According to some implementations, at least a portion of the first etch stop layer 185a positioned on the other side of the first upper insulating structure 320a may be positioned between the first upper insulating structure 320a and the first source/drain pattern 150a, and another portion of the first etch stop layer 185a may be positioned between the first upper insulating structure 320a and the second silicide pattern SC2.

For example, the first etch stop layer 185a positioned on one side of the first upper insulating structure 320a may include a first portion positioned between the first upper insulating structure 320a and the first source/drain pattern 150a and a second portion positioned between the first upper insulating structure 320a and the first silicide pattern SC1 above the first portion. A first etch stop layer 185a positioned on the other side of the first upper insulating structure 320a may include a first portion positioned between the first upper insulating structure 320a and the first source/drain pattern 150a and a second portion positioned between the first upper insulating structure 320a and the second silicide pattern SC2 above the first portion.

The first source/drain patterns 150a may be spaced apart from each other in the first direction D1. According to some implementations, both sides of the first source/drain pattern 150a may include a portion in contact with the first etch stop layer 185a. For example, a first etch stop layer 185a may be positioned between one side of the first source/drain pattern 150a and the interlayer insulating layer 190, and a first etch stop layer 185a may be positioned between the other side of the first source/drain pattern 150a and the first upper insulating structure 320a.

The first source/drain pattern 150a may be in contact with the first lower insulating structure 310a and may not be in contact with the first upper insulating structure 320a. In other words, the first source/drain pattern 150a may be in contact with the first lower insulating structure 310a and spaced apart from the first upper insulating structure 320a.

In FIGS. 5 and 6, the second upper insulating structure 320b positioned in the NMOSFET region NR may be in contact with the second source/drain pattern 150b in the first direction D1. For example, both sides of the second upper insulating structure 320b may be in contact with the second source/drain pattern 150b.

The second etch stop layer 185b may not be positioned between the second upper insulating structure 320b and the second source/drain pattern 150b. Additionally, the second upper insulating structure 320b may not be in contact with the second etch stop layer 185b.

The second source/drain patterns 150b may be spaced apart from each other in the first direction D1. Additionally, one side of the second source/drain pattern 150b may include a portion in contact with the second etch stop layer 185b, and the other side of the second source/drain pattern 150b may not include a portion in contact with the second etch stop layer 185b. For example, a second etch stop layer 185b may be positioned between one side of the second source/drain pattern 150b and the interlayer insulating layer 190, and a second etch stop layer 185b may not be positioned between the other side of the second source/drain pattern 150b and the second upper insulating structure 320b.

The second source/drain pattern 150b may be in contact with the second insulating structure 300b. For example, the second source/drain pattern 150b may be in contact with the second lower insulating structure 310b and the second upper insulating structure 320b.

The shape of the second source/drain pattern 150b may be different from the shape of the first source/drain pattern 150a. According to some implementations, the second source/drain pattern 150b may include a portion protruding in the first direction D1. For example, the second source/drain pattern 150b may include a portion protruding toward the second upper insulating structure 320b. Specifically, the second source/drain pattern 150b may include a portion protruding toward the second upper insulating structure 320b at a higher level than the second lower insulating structure 310b.

In FIG. 5, a portion of the outer surface of the second upper insulating structure 320b in contact with the third silicide pattern SC3 and the fourth silicide pattern SC4 may have a substantially flat shape in cross-section, but the present disclosure is not limited thereto.

In FIG. 6, the outer surface of the second upper insulating structure 320b in contact with the third silicide pattern SC3 and the fourth silicide pattern SC4 may include a portion having a substantially convex shape in cross-section. For example, the second upper insulating structure 320b may include a portion having a substantially convex shape toward the third silicide pattern SC3 and the fourth silicide pattern SC4.

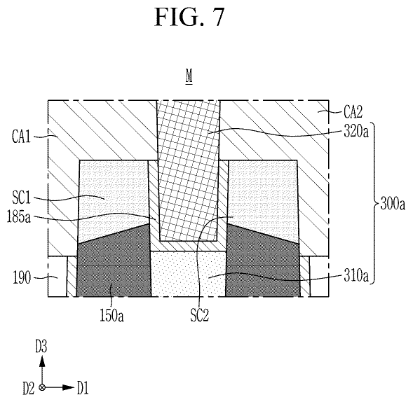

FIG. 7 is an enlarged view of region M of FIG. 4 according to some implementations. The semiconductor device illustrated in FIG. 7 may include components similar to or identical to the semiconductor devices described with reference to FIG. 1 to FIG. 6. However, the semiconductor device in FIG. 7 is different from that illustrated in FIGS. 1 to 6 in that the first etch stop layer 185a surrounds at least a portion of the side surface and the bottom surface of the first upper insulating structure 320a. Here, any overlapping content from the above will be briefly explained or omitted, and the differences will be explained primarily.

In FIG. 7, the M region corresponds to a PMOSFET region PR of a semiconductor device according to some implementations. The first etch stop layer 185a positioned in the PMOSFET region PR may surround at least a portion of the side surface and the bottom surface of the first upper insulating structure 320a. For example, the first etch stop layer 185a may include a third portion positioned on both sides of a portion of the first upper insulating structure 320a and a fourth portion positioned between the first upper insulating structure 320a and the first lower insulating structure 310a. The third portion and the fourth portion of the first etch stop layer 185a may be connected to each other. The third and fourth portions of the first etch stop layer 185a are formed integrally and may surround at least a portion of the side surface and the bottom surface of the first upper insulating structure 320a.

The upper level of the third portion of the first etch stop layer 185a may be lower than the upper level of the first upper insulating structure 320a. According to some implementations, the upper surface of the fourth portion of the first etch stop layer 185a may be in contact with the first upper insulating structure 320a, and the lower surface of the fourth portion of the first etch stop layer 185a may be in contact with the first lower insulating structure 310a.

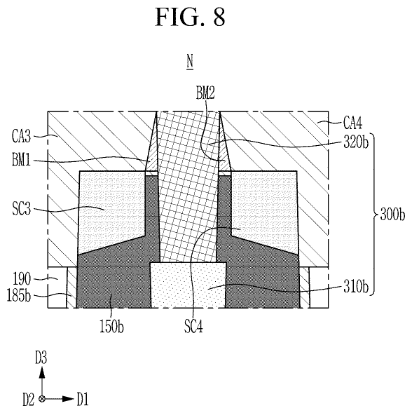

FIG. 8 is an enlarged view of region N of FIG. 4 according to some implementations. The semiconductor device illustrated in FIG. 8 may include components similar to or identical to the semiconductor devices described with reference to FIGS. 1 to 6. However, the semiconductor device in FIG. 8 is different from that illustrated in FIGS. 1 to 6 in that the second upper insulating structure 320b is spaced apart from the third silicide pattern SC3 and the fourth silicide pattern SC4. Here, any overlapping content from the above will be briefly explained or omitted, and the differences will be explained primarily.

In FIG. 8, the N region corresponds to an NMOSFET region NR of a semiconductor device according to some implementations. According to some implementations, a first barrier pattern BM1 and a second barrier pattern BM2 may be positioned between the third contact plug CA3 and the fourth contact plug CA4 disposed in the NMOSFET region NR and the second upper insulating structure 320b, respectively. The first barrier pattern BM1 and the second barrier pattern BM2 may be in contact with side surfaces of the third contact plug CA3 and the fourth contact plug CA4, respectively. For example, one side of the first barrier pattern BM1 may be in contact with the third contact plug CA3, and the other side may be in contact with the second upper insulating structure 320b. For example, one side of the second barrier pattern BM2 may be in contact with the fourth contact plug CA4, and the other side may be in contact with the second upper insulating structure 320b.

According to some implementations, the width of each of the first barrier pattern BM1 and the second barrier pattern BM2 along the first direction D1 may become smaller as it goes upward along the third direction D3. In other words, the width of each of the first barrier pattern BM1 and the second barrier pattern BM2 along the first direction D1 may become smaller as it gets closer to the upper surface of the second upper insulating structure 320b.

Each of the first barrier pattern BM1 and the second barrier pattern BM2 is illustrated as being formed of a single layer, but the present disclosure is not limited thereto, and each of the first barrier pattern BM1 and the second barrier pattern BM2 may be formed of a multilayer including at least one of a conductive metal or a conductive metal nitride.

The first barrier pattern BM1 and the second barrier pattern BM2 may include a conductive metal, a conductive metal nitride, or a combination thereof. The first barrier pattern BM1 and the second barrier pattern BM2 may include a metal such as, for example, titanium Ti, tantalum Ta, or tungsten W. Additionally, for example, the first barrier pattern BM1 and the second barrier pattern BM2 may include a metal nitride such as titanium nitride TiN, tantalum nitride TaN, or tungsten nitride WN.

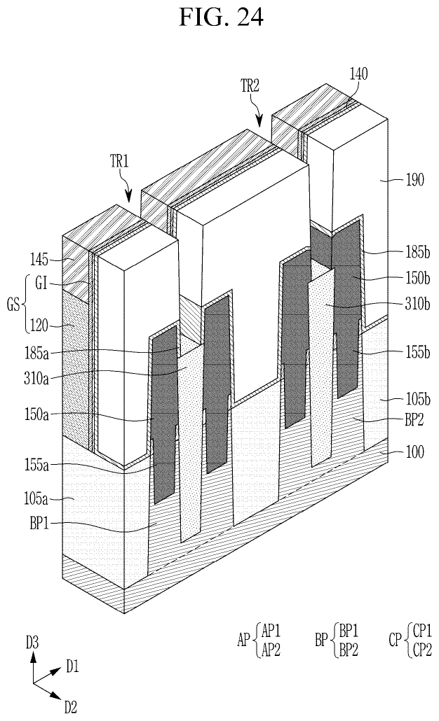

According to some implementations, a second etch stop layer 185b may be positioned beneath each of the first barrier pattern BM1 and the second barrier pattern BM2. In the process described later with reference to FIG. 24, since the second etch stop layer 185b on the second source/drain pattern 150b is not completely removed and remains, the second etch stop layer 185b may be positioned under each of the first barrier pattern BM1 and the second barrier pattern BM2. Accordingly, the second upper insulating structure 320b may include a portion in contact with the second etch stop layer 185b.

The second upper insulating structure 320b may contact the second source/drain pattern 150b in the first direction D1. For example, both sides of the second upper insulating structure 320b may be in contact with the second source/drain pattern 150b. According to some implementations, the second etch stop layer 185b may not be positioned between the second upper insulating structure 320b and the second source/drain pattern 150b.

The second upper insulating structure 320b may not be in contact with each of the third silicide pattern SC3 and the fourth silicide pattern SC4. According to some implementations, the third silicide pattern SC3 and the fourth silicide pattern SC4 may be spaced apart from the second upper insulating structure 320b with the second source/drain pattern 150b therebetween.

FIG. 9 is a cross-sectional view taken along line C-C′ of FIG. 1 according to some implementations. The semiconductor device illustrated in FIG. 9 may include components similar to or identical to the semiconductor devices described with reference to FIGS. 1 to 6. However, the semiconductor device in FIG. 9 has a structure that does not include a lower insulating structure 310, unlike those illustrated in FIGS. 1 to 6. Here, any overlapping content from the above will be briefly explained or omitted, and the differences will be explained primarily.

In FIG. 9, a semiconductor device may include an interlayer insulating layer 190 and a first upper insulating structure 320a positioned between a pair of first source/drain patterns 150a spaced apart from each other in a first direction D1 in a PMOSFET region PR.

The first upper insulating structure 320a is positioned between the first contact plug CA1 and the second contact plug CA2 and may be positioned between at least a portion of a pair of first source/drain patterns 150a. According to some implementations, an interlayer insulating layer 190 may be positioned beneath the first upper insulating structure 320a, and may fill a space between a pair of first source/drain patterns 150a.

According to some implementations, a first etch stop layer 185a may be positioned between the interlayer insulating layer 190 and the first source/drain patterns 150a. According to some implementations, a first etch stop layer 185a may be positioned between the interlayer insulating layer 190 and the first field insulating layer 105a.

A semiconductor device may include an interlayer insulating layer 190 and a second upper insulating structure 320b positioned between a pair of second source/drain patterns 150b spaced apart from each other in a first direction D1 in an NMOSFET region NR.

The second upper insulating structure 320b is positioned between the third contact plug CA3 and the fourth contact plug CA4 and may be positioned between at least a portion of a pair of second source/drain patterns 150b. According to some implementations, an interlayer insulating layer 190 may be positioned beneath the second upper insulating structure 320b, and the interlayer insulating layer 190 may fill a space between a pair of second source/drain patterns 150b.

According to some implementations, a second etch stop layer 185b may be positioned between the interlayer insulating layer 190 and the second source/drain patterns 150b. According to some implementations, a second etch stop layer 185b may be positioned between the interlayer insulating layer 190 and the second field insulating layer 105b.

FIG. 10 is a cross-sectional view taken along line C-C′ of FIG. 1 according to some implementations. The semiconductor device illustrated in FIG. 10 may include components similar to or identical to the semiconductor devices described with reference to FIGS. 1 to 6. However, the semiconductor device in FIG. 10, unlike that illustrated in FIGS. 1 to 6, does not include a lower insulating structure 310 and has a structure in which an air gap AG is positioned inside a second upper insulating structure 320b. Here, any overlapping content from the above will be briefly explained or omitted, and the differences will be explained primarily.

In FIG. 10, a semiconductor device may include a second upper insulating structure 320b positioned between a pair of second source/drain patterns 150b spaced apart from each other in a first direction D1 in an NMOSFET region NR.

The second upper insulating structure 320b may be positioned between the third contact plug CA3 and the fourth contact plug CA4 and between a pair of second source/drain patterns 150b. According to some implementations, an air gap AG may be disposed within the second upper insulating structure 320b. For example, an air gap AG may be disposed between a pair of second source/drain patterns 150b.

In FIG. 10, in a semiconductor device, an air gap, void, or seam may not be positioned in the PMOSFET region PR, and an air gap AG may be positioned in the NMOSFET region NR.

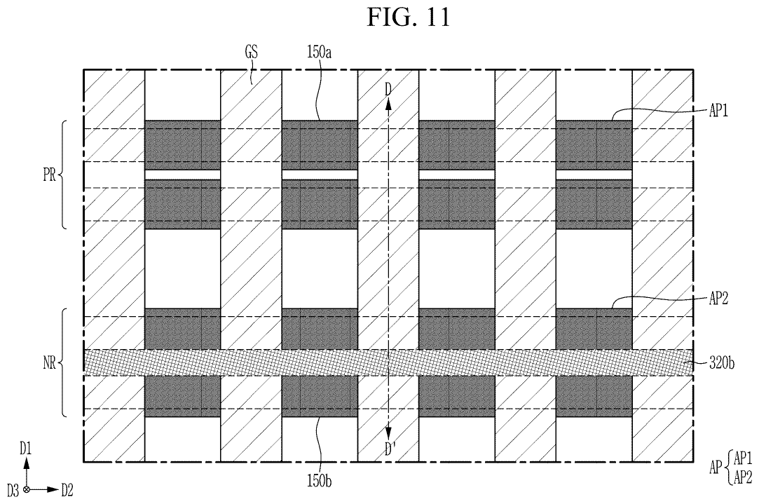

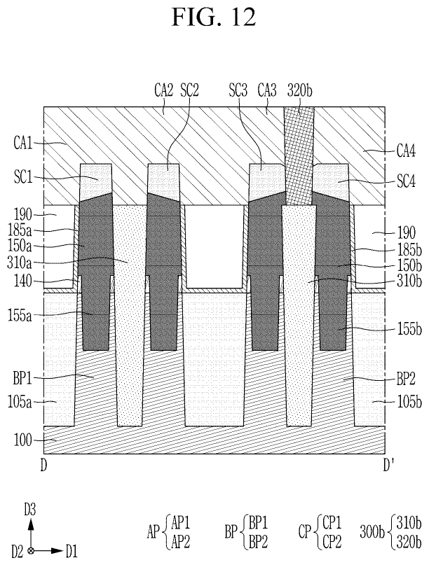

FIG. 11 is a plan view illustrating a semiconductor device according to an some implementations. FIG. 12 is a cross-sectional view taken along line D-D′ of FIG. 11 according to some implementations.

The semiconductor devices illustrated in FIGS. 11 and 12 may include components similar to or identical to the semiconductor devices described with reference to FIGS. 1 to 6. However, the semiconductor device in FIGS. 11 and 12 has a structure in which, unlike those illustrated in FIGS. 1 to 6, an upper insulating structure is not positioned in the PMOSFET region PR, and a second upper insulating structure 320b is positioned in the NMOSFET region NR. Here, any overlapping content from the above will be briefly explained or omitted, and the differences will be explained primarily.

In FIG. 10, in a PMOSFET region PR of a semiconductor device, an upper insulating structure may not be positioned between a pair of first source/drain patterns 150a spaced apart from each other in a first direction D1. In other words, the first source/drain patterns 150a disposed in the PMOSFET region PR may be spaced apart from each other in the first direction D1 even if they are not spaced apart by the upper insulating structure.

According to some implementations, a first contact plug CA1 and a second contact plug CA2, each connected to a pair of first source/drain patterns 150a, may be connected to each other. The first lower insulating structure 310a may separate and space the gate pattern 120 extending in the first direction D1 in the PMOSFET region PR.

According to some implementations, a second insulating structure 300b may be positioned between a pair of second source/drain patterns 150b spaced apart from each other in a first direction D1 in an NMOSFET region NR of a semiconductor device. For example, a second upper insulating structure 320b may be positioned between at least a portion of a pair of second source/drain patterns 150b, and a second lower insulating structure 310b may be positioned below the second upper insulating structure 320b. In other words, the second source/drain patterns 150b disposed in the NMOSFET region NR may be spaced apart from each other in the first direction D1 by the second lower insulating structure 310b and the second upper insulating structure 320b.

The second upper insulating structure 320b may separate the upper portions of the second source/drain patterns 150b from each other in the first direction D1, and the second lower insulating structure 310b may separate the lower portions of the second source/drain patterns 150b from each other in the first direction D1. The second lower insulating structure 310b may separate and space the gate pattern 120 extending in the first direction D1 in the NMOSFET region NR.

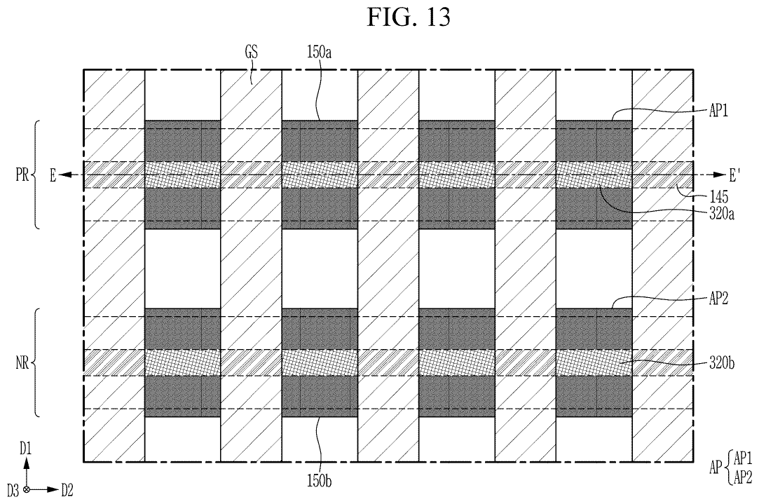

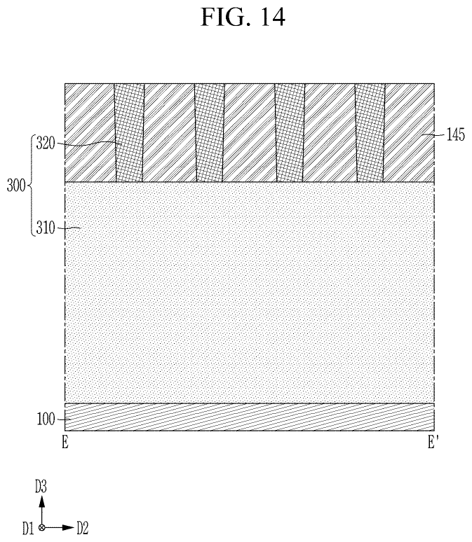

FIG. 13 is a plan view illustrating a semiconductor device according to some implementations. FIG. 14 is a cross-sectional view taken along line E-E′ of FIG. 13 according to some implementations.

The semiconductor devices illustrated in FIGS. 13 and 14 may include components similar to or identical to the semiconductor devices described with reference to FIGS. 1 to 6. However, the semiconductor device in FIGS. 13 and 14 is different from that illustrated in FIGS. 1 to 6 in that the upper insulating structures 320 are spaced apart from each other along the second direction D2. Here, any overlapping content from the above will be briefly explained or omitted, and the differences will be explained primarily.

In FIGS. 13 and 14, the upper insulating structure 320 may be spaced apart in the second direction D2. The upper insulating structure 320 and the capping layer 145 may be arranged alternately along the second direction D2. According to some implementations, a lower insulating structure 310 may be positioned beneath the upper insulating structure 320 and the capping layer 145. The lower insulating structure 310 may extend in the second direction D2 under the upper insulating structure 320 and the capping layer 145.

For example, the first upper insulating structure 320a disposed in the PMOSFET region PR may be spaced apart in the second direction D2. The first upper insulating structure 320a and the capping layer 145 may be arranged alternately along the second direction D2. The first upper insulating structure 320a may overlap the first source/drain patterns 150a in the first direction D1, but may not overlap the first channel patterns CP1.

The second upper insulating structure 320b positioned in the NMOSFET region NR may be spaced apart in the second direction D2.The second upper insulating structure 320b and the capping layer 145 may be arranged alternately along the second direction D2. The second upper insulating structure 320b may overlap the second source/drain patterns 150b in the first direction D1, but may not overlap the second channel patterns CP2.

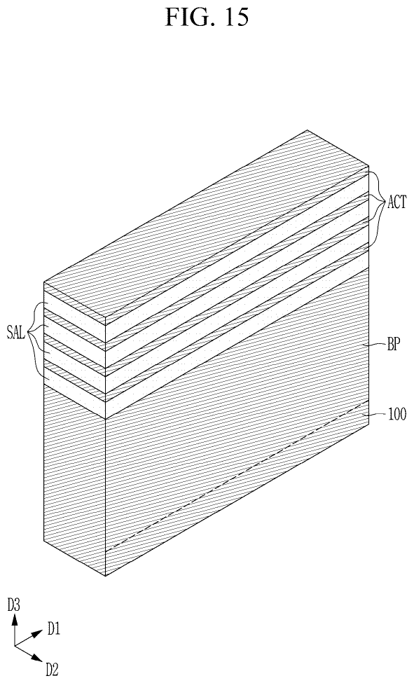

FIGS. 15 to 26 are cross-sectional views illustrating examples of intermediate steps of a method of manufacturing a semiconductor device according to some implementations. For example, FIGS. 15 to 26 are perspective views of each manufacturing process step of a semiconductor device according to some implementations.

In FIG. 15, sacrificial layers SAL and active layers ACT may be formed alternately stacked on a substrate 100. The sacrificial layers SAL may include silicon (Si), germanium (Ge), or silicon-germanium (SiGe), and the active layers ACT may include silicon (Si), germanium (Ge), or silicon-germanium (SiGe). For example, the sacrificial layers SAL may include silicon germanium (SiGe), and the active layers ACT may include silicon (Si). The concentration of germanium (Ge) in each of the sacrificial layers SAL may be 10 at % to 30 at %.

In FIG. 16, mask patterns may be formed on the substrate 100. The mask pattern may have a line shape or a bar shape extending in the second direction D2.

According to some implementations, a patterning process may be performed using mask patterns as etching masks to form trenches defining a first active pattern AP1 and a second active pattern AP2. Accordingly, a pair of first active patterns AP1 and a pair of second active patterns AP2 may be formed. A PMOSFET region PR and an NMOSFET region NR may be defined by first active patterns AP1 and second active patterns AP2 positioned on a substrate 100. In other words, the first active patterns AP1 and the second active patterns AP2 may be placed in the PMOSFET region PR and the NMOSFET region NR, respectively.

The first active pattern AP1 may include a first lower pattern BP1 and a first channel pattern CP1. Sacrificial layers SAL and first channel patterns CP1 may be alternately stacked on top of the first lower pattern BP1. The first lower pattern BP1 and the sacrificial layers SAL and the first channel patterns CP1 alternately stacked on top of the first lower pattern BP1 may be referred to as a first stacked structure.

The second active pattern AP2 may include a second lower pattern BP2 and a second channel pattern CP2. Sacrificial layers SAL and second channel patterns CP2 may be alternately stacked on top of the second lower pattern BP2. The second lower pattern BP2 and the sacrificial layers SAL and second channel patterns CP2 alternately stacked on top of the second lower pattern BP2 may be referred to as a second stacked structure.

According to some implementations, the mask pattern may be removed after the first active patterns AP1 and the second active patterns AP2 are formed.

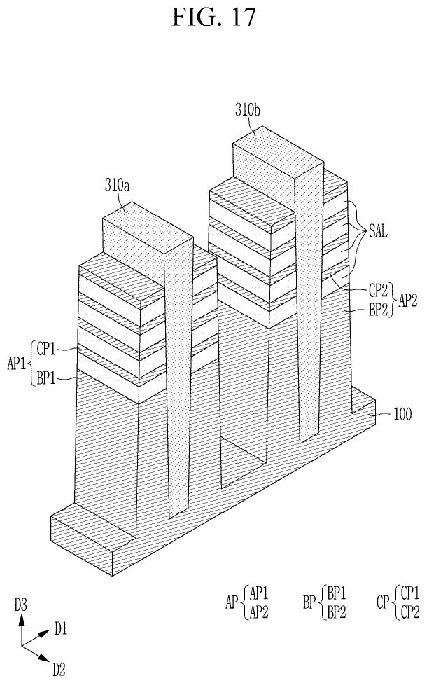

In FIG. 17, a first lower insulating structure 310a and a second lower insulating structure 310b may be formed between a pair of first active patterns AP1 and between a pair of second active patterns AP2, respectively.

The first lower insulating structure 310a may fill a space between the first laminated structures. The second lower insulating structure 310b may fill a space between the second laminated structures.

The first lower insulating structure 310a and the second lower insulating structure 310b may include an insulating material. For example, the first lower insulating structure 310a and the second lower insulating structure 310b may include, but the present disclosure is not limited to, silicon oxide (SiO₂), and may also include silicon nitride (SiON), silicon carbonitride (SiOCN), silicon oxycarbide (SiOC), or a combination thereof.

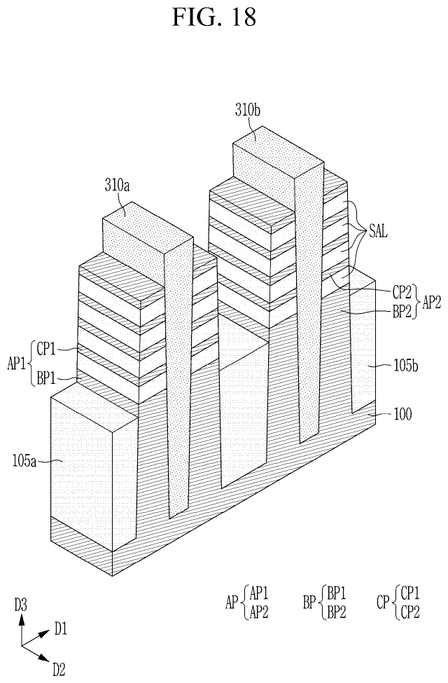

In FIG. 18, first and second field insulating layers 105a and 105b are formed to fill a trench on a substrate 100. For example, the first and second field insulating layers 105a and 105b may be formed to cover both the first active patterns AP1 and the second active patterns AP2. Next, the sacrificial layers SAL on top of the first lower patterns BP1 and the second lower patterns BP2 are exposed.

For example, mask patterns are formed on the first active patterns AP1 and the second active patterns AP2, and a patterning process is performed using the mask patterns as an etching mask to recess the first and second field insulating layers 105a and 105b until the sacrificial layers SAL are exposed.

Thereby, the upper portions of the first active patterns AP1 may be exposed on the first field insulating layer 105a, and the upper portions of the second active patterns AP2 may be exposed on the second field insulating layer 105b. In other words, the upper portions of the first active patterns AP1 may protrude in the third direction D3 more than the first field insulating layer 105a, and the upper portions of the second active patterns AP2 may protrude in the third direction D3 more than the second field insulating layer 105b.

For example, the first and second field insulating layers 105a and 105b may include an insulating material, such as a silicon oxide layer.

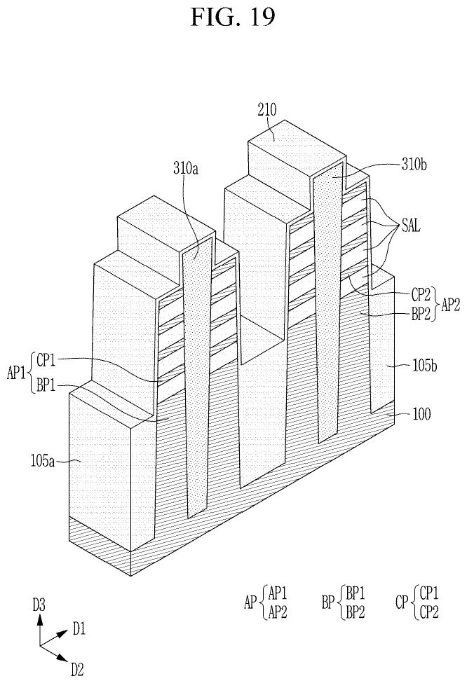

In FIG. 19, a first sacrificial layer 210 covering the first and second field insulating layers 105a and 105b, the first lower insulating structure 310a, and the second lower insulating structure 310b may be formed on the front surface of the substrate 100.

The first sacrificial layer 210 may be formed to cover a laminated structure in which the first lower pattern BP1, sacrificial layers SAL, and first channel patterns CP1 are alternately laminated. Additionally, the first sacrificial layer 210 may be formed to cover a laminated structure in which the second lower pattern BP2, sacrificial layers SAL, and second channel patterns CP2 are alternately laminated.

In a method for manufacturing a semiconductor device according to some implementations, a first sacrificial layer 210 may be formed on an exposed surface as trenches defining a first active pattern AP1 and a second active pattern AP2 are formed. The first sacrificial layer 210 may be placed on the bottom surface and inner surfaces of the trench between the first active pattern AP1 and the second active pattern AP2. That is, the first sacrificial layer 210 may conformally cover the inner wall of the trench.

The first sacrificial layer 210 may include an insulating material, such as a silicon oxide layer. The first sacrificial layer 210 may be formed by one of a physical vapor deposition (PVD) process, a chemical vapor deposition (CVD) process, or an atomic layer deposition (ALD) process.

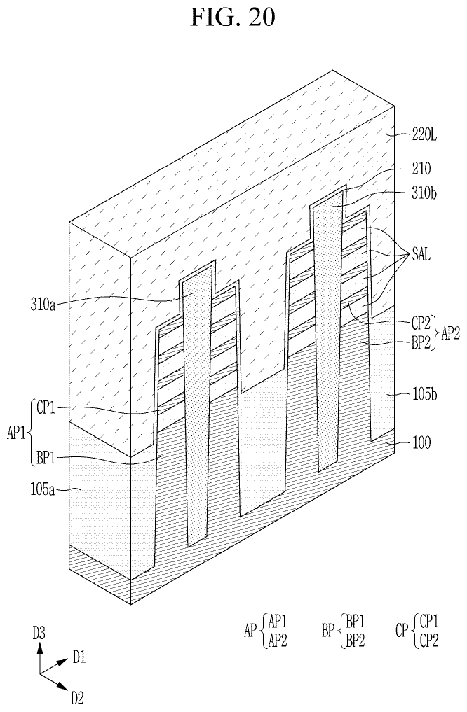

In FIG. 20, a second sacrificial layer 220L covering a first sacrificial layer 210 may be formed on the front surface of the substrate 100. For example, the second sacrificial layer 220L may include polysilicon.

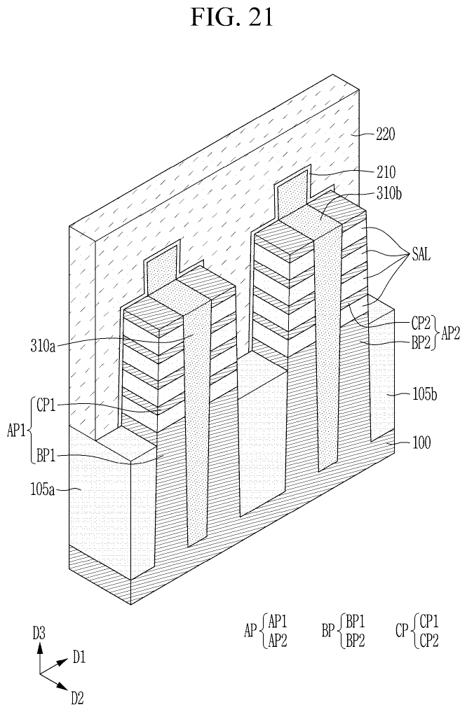

In FIG. 21, a hard mask pattern may be formed on a second sacrificial layer 220L, and the second sacrificial layer 220L may be patterned using the hard mask pattern as an etching mask to form a sacrificial pattern 220.

The sacrificial pattern 220 may be formed in a line shape or a bar shape extending in the first direction D1. Additionally, the sacrificial patterns 220 may be arranged along the second direction D2 at a predetermined pitch.

According to some implementations, at least a portion of the first lower insulating structure 310a and the second lower insulating structure 310b that are exposed when the second sacrificial layer 220L is removed may be removed. For example, the first lower insulating structure 310a protruding in the third direction D3 may be removed more than the laminated structure in which sacrificial layers SAL and first channel patterns CP1 are alternately laminated. Additionally, for example, the second lower insulating structure 310b protruding in the third direction D3 more than the laminated structure in which sacrificial layers SAL and second channel patterns CP2 are alternately laminated may be removed.

Accordingly, the upper level of the first lower insulating structure 310a may be substantially identical to a laminated structure in which sacrificial layers SAL and first channel patterns CP1 are alternately laminated. In addition, accordingly, the upper level of the second lower insulating structure 310b may be substantially identical to a laminated structure in which sacrificial layers SAL and second channel patterns CP2 are alternately laminated.

The first lower insulating structure 310a and the second lower insulating structure 310b covered by the second sacrificial layer 220L may not be removed. Accordingly, the upper levels of the first lower insulating structure 310a and the second lower insulating structure 310b along the second direction D2 may not be constant. In other words, the upper levels of the first lower insulating structure 310a and the second lower insulating structure 310b along the second direction D2 may be irregular and uneven.

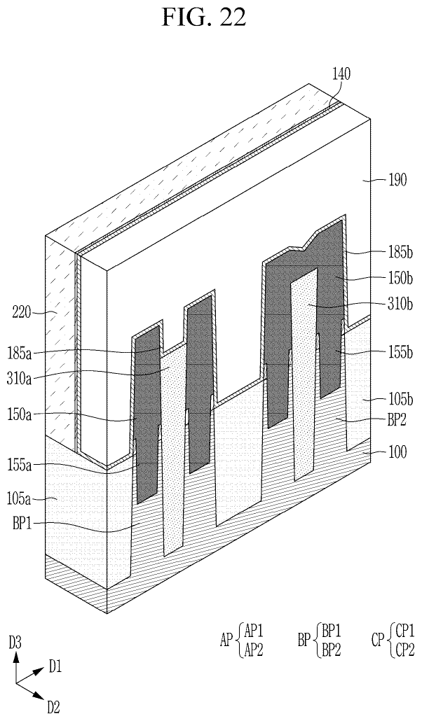

In FIG. 22, a pair of gate spacers 140 may be formed on each of the two sidewalls of the sacrificial pattern 220, first and second source/drain patterns 150a and 150b may be formed, and first and second etch stop layers 185a and 185b and an interlayer insulating layer 190 may be sequentially formed.

For example, a gate spacer layer may be conformally formed on the entire surface of a substrate 100, and the gate spacer layer may be anisotropically etched to form a gate spacer 140.

For example, the gate spacer layer may include SiCN, SiCON, SiN, or a combination thereof. Additionally, the gate spacer layer may be formed of a multi-layer including SiCN, SiCON, SiN, or a combination thereof.

According to some implementations, recesses exposing a first active pattern AP1 may be formed, and a first source/drain pattern 150a and a first dummy source/drain pattern 155a may be formed within the recesses. Similarly, recesses exposing the second active pattern AP2 may be formed, and a second source/drain pattern 150b and a second dummy source/drain pattern 155b may be formed within the recesses. At this time, the first source/drain patterns 150a may be formed on the first lower patterns BP1, and the second source/drain patterns 150b may be formed on the second lower patterns BP2.

For example, a pair of first source/drain patterns 150a may be formed on a pair of first lower patterns BP1 spaced apart from each other in the first direction D1. Similarly, a pair of second source/drain patterns 150b may be formed on a pair of second lower patterns BP2 spaced apart from each other in the first direction D1.

The first source/drain patterns 150a and the second source/drain patterns 150b may include different types of impurities. The first source/drain patterns 150a may include p-type impurities (or p-type dopants). For example, the first source/drain patterns 150a may include B, V, In, Ga, Al, or a combination thereof. The second source/drain patterns 150b may include n-type impurities (or n-type dopants). For example, the second source/drain patterns 150b may include P, Sb, As, or a combination thereof.

At this time, in the cross-section along the first direction D1 and the third direction D3, a pair of first source/drain patterns 150a may be formed to be spaced apart from each other, and a pair of second source/drain patterns 150b may be formed to be connected to each other. In other words, a pair of first source/drain patterns 150a of the PMOSFET region PR may be formed to be spaced apart from each other, and a pair of second source/drain patterns 150b of the NMOSFET region NR may be formed to be connected to each other.

According to some implementations, a first selective epitaxial growth (SEG) process may be performed using an inner wall of the recess as a seed layer to form a first source/drain layer of each of the first source/drain patterns 150a and the second source/drain patterns 150b. The first source/drain layer may be grown using the channel patterns CP and the lower pattern BP exposed by the recess as seeds. For example, the first SEG process may include a chemical vapor deposition (CVD) process or a molecular beam epitaxy (MBE) process.

For example, the first source/drain layer may contain a relatively low concentration of germanium (Ge). As another example, the first source/drain layer may contain only silicon (Si) without germanium (Ge).

A second SEG process may be performed on the first source/drain layer to form a second source/drain layer. The second source/drain layer may be formed to completely fill the recess. For example, the second source/drain layer may contain a relatively high concentration of germanium (Ge).

The first dummy source/drain pattern 155a may penetrate at least a portion of the first lower pattern BP1. For example, the first dummy source/drain pattern 155a may be embedded within the first lower pattern BP1. The first dummy source/drain pattern 155a may be disposed below the first source/drain pattern 150a.

The second dummy source/drain pattern 155b may penetrate at least a portion of the second lower pattern BP2. For example, the second dummy source/drain pattern 155b may be embedded within the second lower pattern BP2. The second dummy source/drain pattern 155b may be disposed below the second source/drain pattern 150b.

For example, the first dummy source/drain pattern 155a and the second dummy source/drain pattern 155b may include the same material as the first source/drain pattern 150a and the second source/drain pattern 150b, respectively. For example, the first dummy source/drain pattern 155a and the second dummy source/drain pattern 155b include silicon (Si) or silicon germanium (SiGe), and may further include carbon (C), silicon (Si), germanium (Ge), or tin (Sn).

According to some implementations, at least a portion of the first lower insulating structure 310a and the second lower insulating structure 310b may be recessed. Accordingly, the upper levels of the first lower insulating structure 310a and the second lower insulating structure 310b may be lowered.

Next, first and second etch stop layers 185a and 185b and an interlayer insulating layer 190 may be sequentially formed on the first and second source/drain patterns 150a and 150b.

The first etch stop layer 185a may be formed with a uniform thickness on the upper surface of the first source/drain patterns 150a and the side surface of the gate spacer 140. The second etch stop layer 185b may be formed with a uniform thickness on the upper surface of the second source/drain patterns 150b and the side surface of the gate spacer 140. At this time, the first etch stop layer 185a and the second etch stop layer 185b may be formed integrally in the same process.

For example, the first and second etch stop layers 185a and 185b may be formed by one of a physical vapor deposition (PVD) process, a chemical vapor deposition (CVD) process, or an atomic layer deposition (ALD) process.

The first and second etch stop layers 185a and 185b may include a material having an etching selectivity with respect to the first and second source/drain patterns 150a and 150b. The first and second etch stop layers 185a and 185b may include, for example, at least one of silicon nitride (SiN), silicon oxynitride (SiON), silicon carbonate (SiOCN), silicon boron nitride (SiBN), silicon oxyboron nitride (SiOBN), silicon oxycarbide (SiOC), and combinations thereof.

The interlayer insulating layer 190 may be positioned on the first and second etch stop layers 185a and 185b. The interlayer insulating layer 190 may include a material having an etching selectivity with respect to the first and second etch stop layers 185a and 185b. For example, the interlayer insulating layer 190 may include a silicon oxide layer.

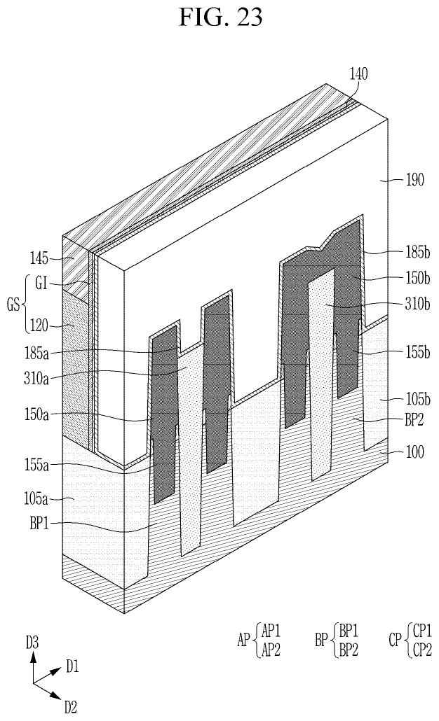

In FIG. 23, the sacrificial pattern 220 and the sacrificial layers SAL illustrated in FIG. 21 may be removed, and a gate structure GS and a capping layer 145 may be formed.

First, the exposed sacrificial pattern 220 may be selectively removed. By removing the sacrificial pattern 220, first empty spaces may be formed that expose the first active pattern AP1 and the second active pattern AP2. Through the first empty space, the sacrificial layers SAL of each of the first active pattern AP1 and the second active pattern AP2 may be exposed.

Next, the sacrificial layers SAL exposed through the first empty spaces may be selectively removed.

For example, by performing an etching process that selectively etches the sacrificial layers SAL, only the sacrificial layers SAL may be removed while leaving the channel patterns CP intact. The etching process may have a high etching rate for silicon-germanium having a relatively high germanium concentration. For example, the etching process may have a high etch rate for silicon-germanium having a germanium concentration greater than about 10 at %.

During the etching process, sacrificial layers SAL on the PMOSFET region PR and NMOSFET region NR may be removed. The etching process may be, for example, wet etching. The etchant used in the etching process may quickly remove the sacrificial layer SAL with a relatively high germanium concentration.

By selectively removing the sacrificial layers SAL, only the channel patterns CP remain on the lower pattern BP. Second empty spaces may be formed through the areas where the sacrificial layers SAL have been removed. The second empty spaces may be disposed between the lower pattern BP and the lowermost channel pattern CP, and between the channel patterns CP.

According to some implementations, at least a portion of the first sacrificial layer 210 illustrated in FIG. 21 may be removed together with the sacrificial pattern 220 and the sacrificial layers SAL.

According to some implementations, a gate insulating layer GI may be formed within the first and second empty spaces. For example, a gate insulating layer GI is conformally formed within the first and second empty spaces. For example, the gate insulator GI may include a high-k material. In some implementations, an inner spacer may be further formed on the gate insulating layer GI.

Next, a gate pattern 120 may be formed on the gate insulating layer GI. For example, a work function layer may be formed on a gate insulating layer GI. Accordingly, three faces of the plurality of channel patterns CP may be surrounded by a work function layer. The work function layer may be formed to surround three faces of the channel patterns CP and at least a portion of the first and second lower insulating structures 310a and 310b.

For example, the work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbon nitride (TaCN), or tantalum carbide (TaC).

Next, a metal filling layer may be formed on the work function layer.

For example, the metal filler layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or combinations thereof.

As described above, a gate pattern 120 may be formed as the work function layer and the metal filling layer are formed sequentially.

Next, a capping layer 145 covering the gate pattern 120 may be formed. The capping layer 145 may cover the first lower insulating structure 310a positioned between the first active patterns AP1 and the second lower insulating structure 310b positioned between the second active patterns AP2.

The capping layer 145 may include, for example, at least one of silicon nitride (SiN), silicon oxynitride (SiON), silicon carbon nitride (SiCN), silicon carbonate nitride (SiOCN), and combinations thereof.

In FIG. 24, a first trench TR1 may be formed by etching from the surface of the capping layer 145 and the interlayer insulating layer 190 to the first lower insulating structure 310a. A second trench TR2 may be formed by etching from the surface of the capping layer 145 and the interlayer insulating layer 190 to the second lower insulating structure 310b.

According to some implementations, a pair of first source/drain patterns 150a on the PMOSFET region PR may be spaced apart from each other in the first direction D1 even before the first trench TR1 is formed. A pair of second source/drain patterns 150b on the NMOSFET region NR may be spaced apart from each other in the first direction D1 as the second trench TR2 is formed.

The first trench TR1 and the second trench TR2 may each have a line shape or a bar shape extending in the second direction D2. As the first trench TR1 is formed, the first etch stop layer 185a positioned on one side of each of the first source/drain patterns 150a may be exposed.

The upper surface of the first lower insulating structure 310a may be exposed as the first trench TR1 is formed. However, the present disclosure is not limited to the first etch stop layer 185a on the first lower insulating structure 310a may not be removed. In this case, as described above with reference to FIG. 7, the first etch stop layer 185a may remain on the first lower insulating structure 310a.

According to some implementations, one side of each of the second source/drain patterns 150b may be exposed as the second trench TR2 is formed. The upper surface of the second lower insulating structure 310b may be exposed as the second trench TR2 is formed.

As described above, in the PMOSFET region PR, as the first trench TR1 is formed, the first etch stop layer 185a positioned on one side of each of the first source/drain patterns 150a is exposed, and in the NMOSFET region NR, as the second trench TR2 is formed, one side of each of the second source/drain patterns 150b may be exposed.

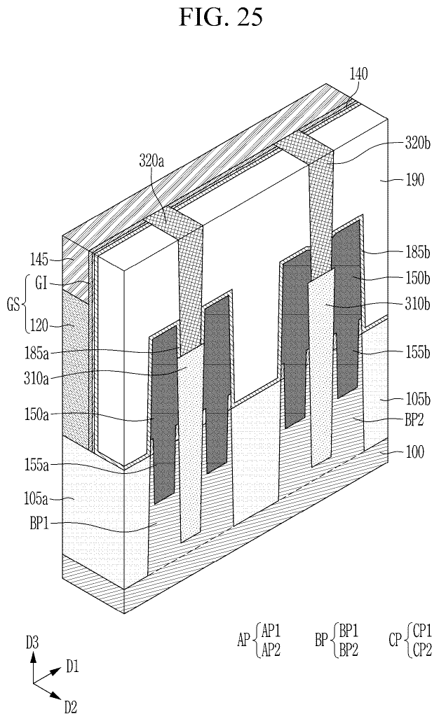

In FIG. 25, a first upper insulating structure 320a and a second upper insulating structure 320b may be formed to fill the first trench TR1 and the second trench TR2, respectively. Accordingly, the first upper insulating structure 320a may penetrate the interlayer insulating layer 190 and be positioned between a pair of first source/drain patterns 150a. A second upper insulating structure 320b may be positioned between a pair of second source/drain patterns 150b penetrating the interlayer insulating layer 190.

According to some implementations, a first etch stop layer 185a may be positioned on both sides of the first upper insulating structure 320a. For example, a first etch stop layer 185a may be positioned between the first upper insulating structure 320a and the first source/drain patterns 150a. Accordingly, the first upper insulating structure 320a may be spaced apart from the first source/drain patterns 150a in the first direction D1.

The second etch stop layer 185b may not be positioned between the second upper insulating structure 320b and the second source/drain patterns 150b. Accordingly, the second upper insulating structure 320b may come into contact with the second source/drain patterns 150b in the first direction D1.

For example, the first and second upper insulating structures 320a and 320b may each include the same material as the first and second lower insulating structures 310a and 310b. At this time, the boundary between the first upper insulating structure 320a and the first lower insulating structure 310a and the boundary between the second upper insulating structure 320b and the second lower insulating structure 310b may not be recognized. However, the present disclosure is not limited thereto, and the first and second upper insulating structures 320a and 320b and the first and second lower insulating structures 310a and 310b may include different materials.

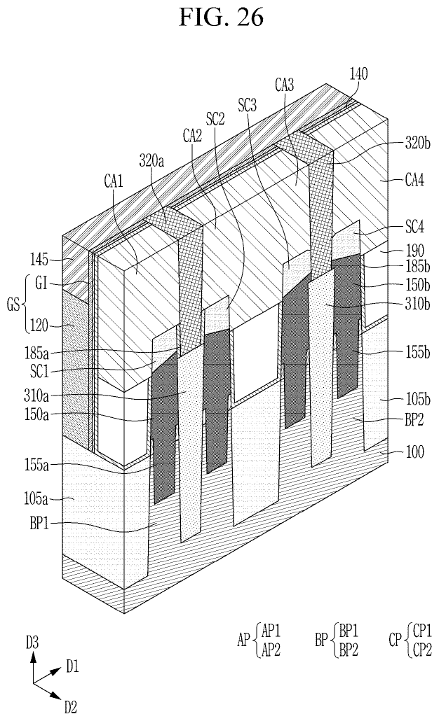

In FIG. 26, a first contact plug CA1 and a second contact plug CA2 each connected to a pair of first source/drain patterns 150a, and a third contact plug CA3 and a fourth contact plug CA4 each connected to a pair of second source/drain patterns 150b may be formed. At this time, the first to fourth contact plugs CA1, CA2, CA3 and CA4 may be formed together. Additionally, the second contact plug CA2 and the third contact plug CA3 may be connected to each other. However, the present disclosure is not limited thereto, and in some implementations, the second contact plug CA2 and the third contact plug CA3 may be separated from each other.

According to some implementations, a contact trench may be formed through the interlayer insulating layer 190 to expose the first source/drain pattern 150a and/or the second source/drain pattern 150b. The contact trench may be formed through an etching process. For example, the etching process may be performed using wet etching, but the present disclosure is not limited thereto.

Next, a first contact plug CA1 and a second contact plug CA2 connected to the first source/drain patterns 150a and a third contact plug CA3 and a fourth contact plug CA4 connected to the second source/drain patterns 150b may be formed by filling the contact trench.

At this time, the first contact plug CA1 and the second contact plug CA2 may be separated in the first direction D1 by the first upper insulating structure 320a. The third contact plug CA3 and the fourth contact plug CA4 may be separated in the first direction D1 by the second upper insulating structure 320b.

According to some implementations, a first silicide pattern SC1 and a first silicide pattern SC2 may be formed between the first contact plug CA1 and the second contact plug CA2 and the first source/drain patterns 150a, respectively. The first contact plug CA1 and the second contact plug CA2 may be electrically connected to the first source/drain pattern 150a through the first silicide pattern SC1 and the second silicide pattern SC2, respectively.

As the first silicide pattern SC1 is formed, a first etch stop layer 185a may be positioned between the first silicide pattern SC1 and the first upper insulating structure 320a. One side of the first etch stop layer 185a positioned between the first silicide pattern SC1 and the first upper insulating structure 320a may be in contact with the first upper insulating structure 320a, and the other side may be in contact with the first silicide pattern SC1.

As the second silicide pattern SC2 is formed, a first etch stop layer 185a may be positioned between the second silicide pattern SC2 and the first upper insulating structure 320a. One side of the first etch stop layer 185a positioned between the second silicide pattern SC2 and the first upper insulating structure 320a may be in contact with the first upper insulating structure 320a, and the other side may be in contact with the second silicide pattern SC2.

According to some implementations, a third silicide pattern SC3 and a fourth silicide pattern SC4 may be formed between the third contact plug CA3 and the fourth contact plug CA4 and the second source/drain patterns 150b, respectively. The third contact plug CA3 and the fourth contact plug CA4 may be electrically connected to the second source/drain patterns 150b through the third silicide pattern SC3 and the fourth silicide pattern SC4, respectively.

As the third silicide pattern SC3 and the fourth silicide pattern SC4 are formed, the third silicide pattern SC3 and the fourth silicide pattern SC4 may be positioned on both sides of the second upper insulating structure 320b. For example, a third silicide pattern SC3 may be positioned on one side of the second upper insulating structure 320b, and a fourth silicide pattern SC4 may be positioned on the other side. One side of the second upper insulating structure 320b may be in contact with the third silicide pattern SC3, and the other side of the second upper insulating structure 320b may be in contact with the fourth silicide pattern SC4.

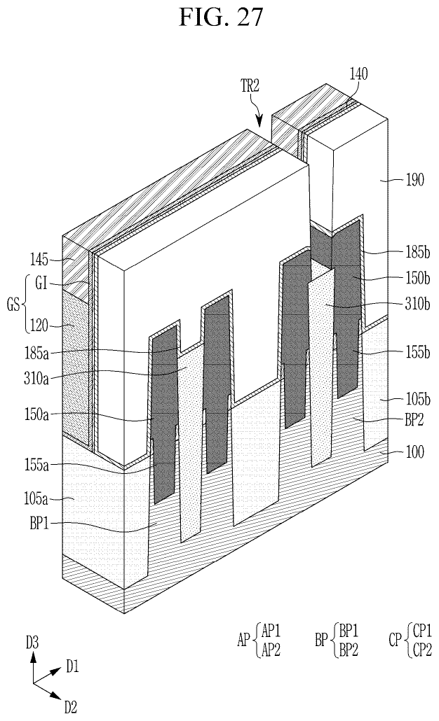

FIGS. 27 to 29 are cross-sectional views illustrating examples of intermediate steps of a method of manufacturing a semiconductor device according to some implementations. Specifically, FIGS. 27 to 29 are perspective views of each manufacturing process step of a semiconductor device according to some implementations.

The method for manufacturing a semiconductor device in FIGS. 27 to 29 is different from that illustrated in FIGS. 24 to 26 in that the method in FIGS. 27 to 29 relates to a method of forming a second trench TR2 in an NMOSFET region NR without forming a first trench TR1 in a PMOSFET region PR. Here, any overlapping content from the above will be briefly explained or omitted, and the differences will be explained primarily.

In FIG. 27, a second trench TR2 may be formed by etching from the surface of the capping layer 145 and the interlayer insulating layer 190 on the NMOSFET region NR to the second lower insulating structure 310b. At this time, the surface of the capping layer 145 and the interlayer insulating layer 190 on the PMOSFET region PR may not be etched up to the first lower insulating structure 310a.

The second trench TR2 may have a line shape or a bar shape extending in the second direction D2.

According to some implementations, one side of each of the second source/drain patterns 150b may be exposed as the second trench TR2 is formed. The upper surface of the second lower insulating structure 310b may be exposed as the second trench TR2 is formed.

According to some implementations, a pair of first source/drain patterns 150a on the PMOSFET region PR may be spaced apart from each other in the first direction D1 even if the first trench TR1 is not formed. According to some implementations, a pair of second source/drain patterns 150b on the NMOSFET region NR may be spaced apart from each other in the first direction D1 as the second trench TR2 is formed.

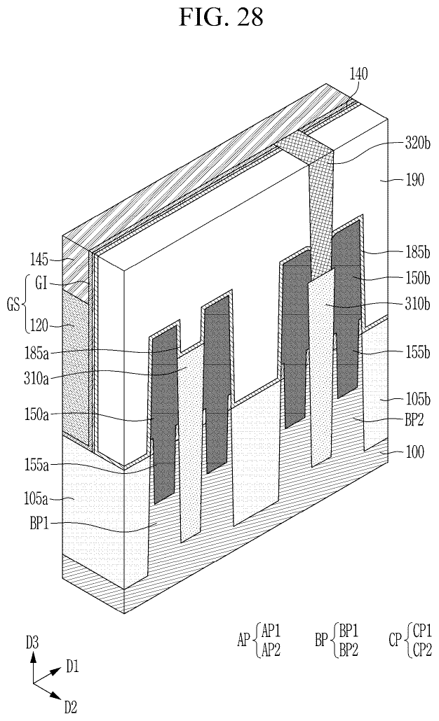

In FIG. 28, a second upper insulating structure 320b filling the second trench TR2 may be formed. Accordingly, the second upper insulating structure 320b may penetrate the interlayer insulating layer 190 and be positioned between a pair of second source/drain patterns 150b.

The second etch stop layer 185b may not be positioned between the second upper insulating structure 320b and the second source/drain patterns 150b. Accordingly, the second upper insulating structure 320b may come into contact with the second source/drain patterns 150b in the first direction D1.

For example, the second upper insulating structure 320b may include the same material as the second lower insulating structure 310b. At this time, the boundary between the second upper insulating structure 320b and the second lower insulating structure 310b may not be recognized. However, the present disclosure is not limited to the above, and the second upper insulating structure 320b and the second lower insulating structure 310b may include different materials.

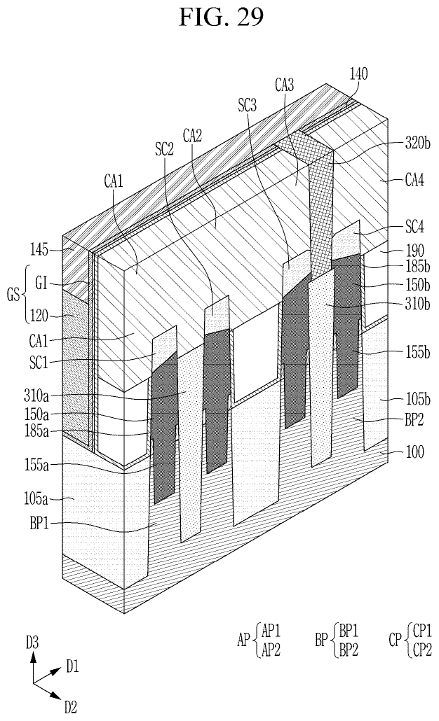

In FIG. 29, a first contact plug CA1 and a second contact plug CA2 each connected to a pair of first source/drain patterns 150a, and a third contact plug CA3 and a fourth contact plug CA4 each connected to a pair of second source/drain patterns 150b may be formed.

According to some implementations, a contact trench may be formed through the interlayer insulating layer 190 to expose the first source/drain pattern 150a and/or the second source/drain pattern 150b. According to some implementations, a contact trench may be formed through an etching process. For example, the etching process may be performed using wet etching, but is not limited thereto.

Next, a first contact plug CA1 and a second contact plug CA2 connected to the first source/drain patterns 150a and a third contact plug CA3 and a fourth contact plug CA4 connected to the second source/drain patterns 150b may be formed by filling the contact trench. At this time, the first to fourth contact plugs CA1, CA2, CA3 and CA4 may be formed together. Additionally, the first contact plug CA1 to the third contact plug CA3 may all be formed to be connected integrally. However, the present disclosure is not limited thereto, and in some implementations, the second contact plug CA2 and the third contact plug CA3 may be separated from each other.

At this time, the first contact plug CA1 and the second contact plug CA2 may be connected to each other in the first direction D1. The third contact plug CA3 and the fourth contact plug CA4 may be separated in the first direction D1 by the second upper insulating structure 320b.

According to some implementations, a first silicide pattern SC1 and a second silicide pattern SC2 may be formed between the first contact plug CA1 and the second contact plug CA2 and the first source/drain patterns 150a, respectively. The first contact plug CA1 and the second contact plug CA2 may be electrically connected to the first source/drain pattern 150a through the first silicide pattern SC1 and the second silicide pattern SC2, respectively.

According to some implementations, a third silicide pattern SC3 and a fourth silicide pattern SC4 may be formed between the third contact plug CA3 and the fourth contact plug CA4 and the second source/drain patterns 150b, respectively. The third contact plug CA3 and the fourth contact plug CA4 may be electrically connected to the second source/drain patterns 150b through the third silicide pattern SC3 and the fourth silicide pattern SC4, respectively.

As the third silicide pattern SC3 and the fourth silicide pattern SC4 are formed, the third silicide pattern SC3 and the fourth silicide pattern SC4 may be positioned on both sides of the second upper insulating structure 320b. For example, a third silicide pattern SC3 may be positioned on one side of the second upper insulating structure 320b, and a fourth silicide pattern SC4 may be positioned on the other side. One side of the second upper insulating structure 320b may be in contact with the third silicide pattern SC3, and the other side of the second upper insulating structure 320b may be in contact with the fourth silicide pattern SC4.

Accordingly, as shown in FIGS. 11 and 12, a structure may be formed in which no upper insulating structure is positioned in the PMOSFET region PR and a second upper insulating structure 320b is positioned in the NMOSFET region NR.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate including a PMOSFET region and an NMOSFET region;
a pair of first channel patterns spaced apart in a first direction on the PMOSFET region;
first source/drain patterns at respective sides of each first channel pattern of the pair of first channel patterns in a second direction crossing the first direction;
a first gate pattern surrounding at least a portion of the pair of first channel patterns;
a pair of second channel patterns spaced apart in the first direction on the NMOSFET region;
second source/drain patterns at respective sides of each second channel pattern of the pair of second channel patterns in the second direction;
a second gate pattern surrounding at least a portion of the pair of second channel patterns;
a first upper insulating structure between a pair of the first source/drain patterns at a first side of the pair of first channel patterns; and
a second upper insulating structure between a pair of the second source/drain patterns at a first side of the pair of second channel patterns,
wherein the first upper insulating structure is spaced apart from the first source/drain patterns in the first direction,
wherein at least a portion of the second upper insulating structure is in contact with the second source/drain patterns,
wherein a bottom level of the first upper insulating structure is higher than bottom levels of the pair of first source/drain patterns, and
wherein a bottom level of the second upper insulating structure is higher than bottom levels of the pair of second source/drain patterns.

2. The semiconductor device of claim 1, comprising an etch stop layer between the first upper insulating structure and the first source/drain patterns,
wherein the etch stop layer is excluded from between the second upper insulating structure and the second source/drain patterns, and the second source/drain patterns are in direct contact with the second upper insulating structure.

3. The semiconductor device of claim 2,
wherein the etch stop layer is at a first side of the first upper insulating structure and at a second side of the first upper insulating structure, and
wherein a first side of a portion of the etch stop layer includes a portion contacts the first source/drain pattern and a second side of the portion of the etch stop layer contacts the first upper insulating structure.

4. The semiconductor device of claim 2, wherein the etch stop layer surrounds at least a portion of sidewalls and a bottom surface of the first upper insulating structure.

5. The semiconductor device of claim 1, further comprising:
a first contact plug connected to the pair of first source/drain patterns, and a first silicide pattern between the first contact plug and the first source/drain patterns; and
a second contact plug connected to the pair of second source/drain patterns, and a second silicide pattern between the second contact plug and the second source/drain patterns,
wherein the first silicide pattern is spaced apart from the first upper insulating structure, and the second silicide pattern is in contact with the second upper insulating structure.

6. The semiconductor device of claim 5, comprising an etch stop layer between the first silicide pattern and the first upper insulating structure.

7. The semiconductor device of claim 1, wherein the second upper insulating structure includes a portion having a convex shape in the first direction.

8. The semiconductor device of claim 1, comprising:
a first lower insulating structure under the first upper insulating structure and extending in a third direction crossing the first and second directions between the pair of first source/drain patterns; and
a second lower insulating structure under the second upper insulating structure and extending in the third direction between the pair of second source/drain patterns.

9. The semiconductor device of claim 8,
wherein the first upper insulating structure and the first lower insulating structure comprise different materials, and
wherein the second upper insulating structure and the second lower insulating structure comprise different materials.

10. The semiconductor device of claim 8,
wherein the first upper insulating structure and the first lower insulating structure comprise the same material, and
wherein the second upper insulating structure and the second lower insulating structure comprise the same material.

11. The semiconductor device of claim 1, comprising:
first lower patterns spaced apart in the first direction on the PMOSFET region and second lower patterns spaced apart in the first direction on the NMOSFET region;
a first field insulating layer between the first lower patterns; and
a second field insulating layer between the second lower patterns,
wherein an interlayer insulating layer is between the first field insulating layer and the first upper insulating structure, and between the second field insulating layer and the second upper insulating structure.

12. The semiconductor device of claim 1,
wherein the first upper insulating structure and the second upper insulating structure extend in the second direction,
wherein the first upper insulating structure is between the pair of first channel patterns, and
wherein the second upper insulating structure is between the pair of second channel patterns.

13. The semiconductor device of claim 12,
wherein the first upper insulating structure between the first channel patterns has a bottom level higher than a bottom level of the first upper insulating structure between the first source/drain patterns, and
wherein the second upper insulating structure between the second channel patterns has a bottom level higher than a bottom level of the second upper insulating structure between the second source/drain patterns.

14. The semiconductor device of claim 1,
wherein the first upper insulating structure is spaced apart in the second direction and does not overlap the first channel patterns in the first direction, and
wherein the second upper insulating structure is spaced apart in the second direction and does not overlap the second channel patterns in the first direction.

15. A semiconductor device comprising:
a substrate including a PMOSFET region and an NMOSFET region;
a pair of first channel patterns spaced apart in a first direction on the PMOSFET region;
first source/drain patterns at respective sides of each first channel pattern of the pair of first channel patterns in a second direction crossing the first direction;
a first insulating structure between a pair of the first source/drain patterns at a first side of the first channel patterns;
a first gate pattern surrounding at least a portion of the first channel patterns;
an etch stop layer extending in the first direction between the first insulating structure and each of the pair of first source/drain patterns;
a pair of second channel patterns spaced apart in the first direction on the NMOSFET region;
second source/drain patterns at respective sides of each second channel pattern of the pair of second channel patterns in the second direction;
a second insulating structure between a pair of the second source/drain patterns at a first side of the second channel patterns; and
a second gate pattern surrounding at least a portion of the second channel patterns,
wherein a first side of each source/drain pattern of the second source/drain patterns contacts the second insulating structure in the first direction.

16. The semiconductor device of claim 15, comprising a first contact plug and a second contact plug respectively connected to a first source/drain pattern of the first source/drain patterns and a second source/drain pattern of the second source/drain patterns.

17. The semiconductor device of claim 16,
wherein the first insulating structure comprises a first upper insulating structure that separates the first contact plug in the first direction, and a first lower insulating structure under the first upper insulating structure and extending in a third direction crossing the first direction and the second direction between the pair of first channel patterns; and
wherein the second insulating structure comprises a second upper insulating structure that separates the second contact plug in the first direction, and a second lower insulating structure under the second upper insulating structure and extending in the third direction between the pair of second channel patterns.

18. The semiconductor device of claim 17, wherein the first insulating structure and the second upper insulating structure extend in the second direction.

19. The semiconductor device of claim 17,
wherein a plurality of first upper insulating structures including the first upper insulating structure are spaced apart from each other along the second direction, and
wherein a plurality of second upper insulating structures including the second upper insulating structure are spaced apart from each other along the second direction.

20. A semiconductor device comprising:
a substrate including a PMOSFET region and an NMOSFET region;
a pair of first channel patterns spaced apart in a first direction on the PMOSFET region;
first source/drain patterns at respective sides of each first channel pattern of the pair of first channel patterns in a second direction crossing the first direction;
a first gate pattern surrounding at least a portion of the first channel patterns;
a pair of second channel patterns spaced apart in the first direction on the NMOSFET region;
second source/drain patterns at respective sides of each second channel pattern of the pair of second channel patterns in the second direction;
a second gate pattern surrounding at least a portion of the second channel patterns;
a first insulating structure between a pair of the first source/drain patterns at a first side of the first channel patterns; and
a second insulating structure between a pair of the second source/drain patterns at a first side of the second channel patterns,
wherein an upper level of the first insulating structure is lower than upper levels of the pair of first source/drain patterns, and
wherein an upper level of the second insulating structure is higher than upper levels of the pair of second source/drain patterns.
